(19) United States
(12) Patent Application Publication
(10) Pub. No.: US 2021/0395487 A1
(43) Pub. Date: Dec. 23, 2021

(54) COLORING COMPOSITION, FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Hiroaki IDEI, Shizuoka (JP); Masaomi MAKINO, Shizuoka (JP); Takuro SUGIYAMA, Shizuoka (JP); Tadao SHIBAMOTO, Shizuoka (JP)

(73) Assignee: FUJIFILM Corporation, Tokyo (JP)

(21) Appl. No.: 17/402,624

(22) Filed: Aug. 16, 2021

Related U.S. Application Data
(63) Continuation of application No. PCT/JP2020/008605, filed on Mar. 2, 2020.

(30) Foreign Application Priority Data
Mar. 13, 2019 (JP) 2019-045363

(51) Int. Cl. C08K 5/3417; C09B 47/04; C08K 5/3437; C08K 5/315; C08K 5/32; C08K 5/101; C08K 5/00; G02B 5/22

(52) U.S. Cl. CPC C08K 5/3417; C09B 47/04; C08K 5/3437; C08K 5/315; H01L 27/14621; C08K 5/101; C08K 5/0091; G02B 5/223; C08K 5/32

(57) ABSTRACT

Provided are a coloring composition including a colorant including a green pigment, a compound A, and a resin, in an which amount of the green pigment dissolved in 100 g of propylene glycol methyl ether acetate at 25° C. is less than 0.01 g, an amount of the compound A dissolved in 100 g of propylene glycol methyl ether acetate at 25° C. is 0.01 g or more, the coloring composition includes 0.1 to 10 parts by mass of the compound A with respect to 100 parts by mass of the green pigment, and the green pigment and the compound A satisfy a relationship of “−1.0 eV≤LUMO_{B}−LUMO_{A}≤1.0 eV”; a film; a color filter; a solid-state imaging element; and an image display device. LUMO_{B} is an energy level of a lowest unoccupied molecular orbital of the green pigment, and LUMO_{A} is an energy level of a lowest unoccupied molecular orbital of the compound A.

### CROSS-REFERENCE TO RELATED APPLICATIONS

This application is a Continuation of PCT International Application No. PCT/JP2020/008605 filed on Mar. 2, 2020, which claims priority under 35 U.S.C § 119(a) to Japanese Patent Application No. 2019-045363 filed on Mar. 13, 2019. Each of the above application(s) is hereby expressly incorporated by reference, in its entirety, into the present application.

### BACKGROUND OF THE INVENTION

### 1. Field of the Invention

The present invention relates to a coloring composition including a green pigment.

The present invention further relates to a film using the coloring composition, a color filter, a solid-state imaging element, and an image display device.

### 2. Description of the Related Art

In recent years, as a digital camera, a mobile phone with a camera, and the like have been further spreading, there has been a greatly increasing demand for a solid-state imaging element such as a charge coupled device (CCD) image sensor. As a key device of a display or an optical element, a color filter has been used. The color filter normally includes pixels of three primary colors of red, green, and blue, and acts to separate transmitted light into the three primary colors.

Pixels of each color of the color filter are manufactured using a coloring composition including a colorant.

In addition, JP2016-075739A discloses an invention which relates to a coloring composition for a color filter including a luminescent coloring agent (S), a quencher (A), and a binder resin (C), in which the difference between the energy level LUMOs in the lowest unoccupied molecular orbital of the luminescent coloring agent (S) and the energy level LUMO_{A} in the lowest unoccupied molecular orbital of the quencher (A) satisfies the relational expression of 0.0<|LUMO_{A}|−|LUMO_{S}|<2.0 (eV).

In addition, JP2017-111226A discloses an invention which relates to a coloring curable resin composition including a colorant (A), a resin (B), a polymerizable compound (C), a polymerization initiator (D), and a fluorescence inhibitor (E), in which the colorant (A) includes a xanthene dye (A-1) and the fluorescence inhibitor (E) includes at least one selected from the group consisting of a predetermined tetracyanoquinodimethane derivative and quinone derivative.

### SUMMARY OF THE INVENTION

In a coloring composition using a colorant including a pigment, the viscosity of the coloring composition may increase over time due to aggregation of pigments during storage.

In particular, a green pigment tends to have low dispersibility, and the green pigment tends to aggregate during storage, so that the viscosity of the coloring composition tends to increase over time.

The coloring composition may be used immediately after manufacture, or may be used after being stored for a long time after manufacture. Therefore, further improvement in storage stability of the coloring composition is desired.

Further, JP2016-075739A and JP2017-111226A do not disclose or study storage stability of a coloring composition including the green pigment.

Therefore, an object of the present invention is to provide a coloring composition having excellent storage stability. Another object of the present invention is to provide a film using the coloring composition, a color filter, a solid-state imaging element, and an image display device.

According to the studies conducted by the present inventor, it has been found that the above-described object can be achieved by adopting the following configuration, thereby leading to the completion of the present invention. Therefore, the present invention provides the following.

<1> A coloring composition comprising:

a colorant including a green pigment;

a compound A; and

a resin,

in which an amount of the green pigment dissolved in 100 g of propylene glycol methyl ether acetate at 25° C. is less than 0.01 g,

an amount of the compound A dissolved in 100 g of propylene glycol methyl ether acetate at 25° C. is 0.01 g or more,

the coloring composition includes 0.1 to 10 parts by mass of the compound A with respect to 100 parts by mass of the green pigment, and

the green pigment and the compound A satisfy a relationship of the following expression (a),

−1.0 eV≤LUMO_{B}−LUMO_{A}≤1.0 eV (a)

where LUMO_{B} is an energy level of a lowest unoccupied molecular orbital of the green pigment, in units of eV, and

LUMO_{A} is an energy level of a lowest unoccupied molecular orbital of the compound A, in units of eV.

<2> The coloring composition according to <1>,

in which the energy level of the lowest unoccupied molecular orbital of the compound A is −6.0 to −3.0 eV.

<3> The coloring composition according to <1> or <2>,

in which a specific absorbance of the compound A at a maximum absorption wavelength of 450 to 800 nm, which is represented by the following expression (A_{λ1}), is 50 or less,

E¹=A¹/(c¹×l¹) (A_{λ1})

in the expression (A_{λ1}), E¹ represents the specific absorbance of the compound A at the maximum absorption wavelength of 450 to 800 nm, A¹ represents an absorbance of the compound A at the maximum absorption wavelength of 450 to 800 nm, l¹ represents a cell length in units of cm, and c¹ represents a concentration of the compound A in a solution, in units of mg/ml.

<4> The coloring composition according to any one of <1> to <3>,

in which the green pigment is a halogenated phthalocyanine compound.

<5> The coloring composition according to any one of <1> to <4>, in which the compound A is a compound represented by any of Formula (1) to Formula (7),

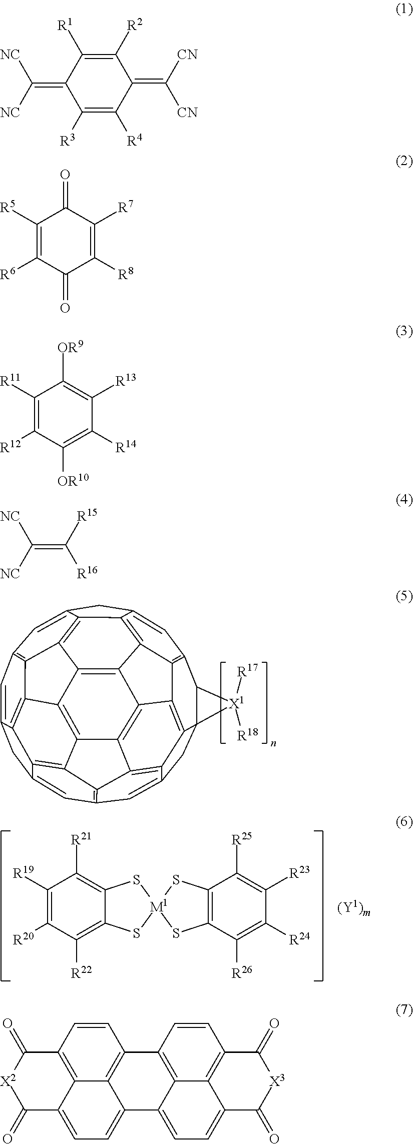

in Formula (1), R¹ to R⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R¹ and R², or R³ and R⁴ may be bonded to each other to form a ring,

in Formula (2), R⁵ to R⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R⁵ and R⁶, or R⁷ and R⁸ may be bonded to each other to form a ring,

in Formula (3), R⁹ and R¹⁰ each independently represent a hydrogen atom, a hydrocarbon group, or a heterocyclic group, R¹¹ to R¹⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹¹ and R¹², or R¹³ and R¹⁴ may be bonded to each other to form a ring,

in Formula (4), R¹⁵ and R¹⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁵ and R¹⁶ may be bonded to each other to form a ring,

in Formula (5), X¹ represents a carbon atom or a silicon atom, n represents an integer of 1 to 5, R¹⁷ and R¹⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁷ and R¹⁸ may be bonded to each other to form a ring,

in Formula (6), M¹ represents a metal atom, R¹⁹ to R²⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, R¹⁹ and R²¹, R¹⁹ and R²⁰, R²⁰ and R²², R²³ and R²⁵, R²³ and R²⁴, or R²⁴ and R²⁶ may be bonded to each other to form a ring, in a case where a moiety enclosed in [ ] in the formula is a cationic moiety, Y¹ represents a counter anion and m represents the number required to balance charges, in a case where a moiety enclosed in [ ] in the formula is an anionic moiety, Y¹ represents a counter cation and m represents the number required to balance charges, and in a case where a charge of a moiety enclosed in [ ] in the formula is neutralized in a molecule, m is 0, and

in Formula (7), X² and X³ each independently represent O or NRx, where Rx represents a hydrogen atom or a substituent.

<6> The coloring composition according to any one of <1> to <5>, in which the resin includes a resin which includes a repeating unit having a graft chain.

<7> The coloring composition according to <6>, in which a weight-average molecular weight of the graft chain is 500 to 100000.

<8> The coloring composition according to any one of <1> to <7>, further comprising:

a pigment derivative.

<9> The coloring composition according to any one of <1> to <8>,

in which the colorant further includes a yellow pigment.

<10> The coloring composition according to <9>,

in which the yellow pigment is at least one selected from an isoindoline compound and a quinophthalone compound.

<11> The coloring composition according to any one of <1> to <10>,

in which a content of the colorant in a total solid content of the coloring composition is 45 mass % or more.

<12> The coloring composition according to any one of <1> to <11>,

in which a content of the green pigment in the colorant is 40 mass % or more.

<13> The coloring composition according to any one of <1> to <12>, further comprising:

a polymerizable compound; and

a photopolymerization initiator.

<14> The coloring composition according to any one of <1> to <13>,

in which the coloring composition is a cyan coloring composition.

<15> A film obtained by using the coloring composition according to any one of <1> to <14>.

<16> A color filter comprising:

the film according to <15>.

<17> A solid-state imaging element comprising:

the film according to <15>.

<18> An image display device comprising:

the film according to <15>.

According to the present invention, it is possible to provide a coloring composition having excellent storage stability. It is also possible to provide a film using the coloring composition, a color filter, a solid-state imaging element, and an image display device.

### DESCRIPTION OF THE PREFERRED EMBODIMENTS

Hereinafter, the details of the present invention will be described.

In the present specification, numerical ranges represented by “to” include numerical values before and after “to” as lower limit values and upper limit values.

In the present specification, unless specified as a substituted group or as an unsubstituted group, a group (atomic group) denotes not only a group (atomic group) having no substituent but also a group (atomic group) having a substituent. For example, “alkyl group” denotes not only an alkyl group having no substituent (unsubstituted alkyl group) but also an alkyl group having a substituent (substituted alkyl group).

In the present specification, unless specified otherwise, “exposure” denotes not only exposure using light but also drawing using a corpuscular beam such as an electron beam or an ion beam. Examples of the light used for exposure include an actinic ray or radiation, for example, a bright light spectrum of a mercury lamp, a far ultraviolet ray represented by excimer laser, an extreme ultraviolet ray (EUV ray), an X-ray, or an electron beam.

In the present specification, “(meth)acrylate” denotes either or both of acrylate and methacrylate, “(meth)acryl” denotes either or both of acryl and methacryl, and “(meth)acryloyl” denotes either or both of acryloyl and methacryloyl.

In the present specification, in structural formulae, Me represents a methyl group, Et represents an ethyl group, Bu represents a butyl group, and Ph represents a phenyl group.

In the present specification, a weight-average molecular weight and a number-average molecular weight are values in terms of polystyrene measured by gel permeation chromatography (GPC) method.

In the present specification, a total solid content denotes the total mass of all the components of the composition excluding a solvent.

In the present specification, a pigment means a compound which is hardly dissolved in a solvent.

In the present specification, the term “step” denotes not only an individual step but also a step which is not clearly distinguishable from another step as long as an effect expected from the step can be achieved.

<Coloring Composition>

The coloring composition according to the embodiment of the present invention includes a colorant including a green pigment, a compound A, and a resin, in which an amount of the green pigment dissolved in 100 g of propylene glycol methyl ether acetate at 25° C. is less than 0.01 g, an amount of the compound A dissolved in 100 g of propylene glycol methyl ether acetate at 25° C. is 0.01 g or more, the coloring composition includes 0.1 to 10 parts by mass of the compound A with respect to 100 parts by mass of the green pigment, and the green pigment and the compound A satisfy a relationship of the following expression (a).

−1.0 eV≤LUMO_{B}−LUMO_{A}≤1.0 eV (a)

LUMO_{B} is an energy level of a lowest unoccupied molecular orbital of the green pigment, in units of eV, and

LUMO_{A} is an energy level of a lowest unoccupied molecular orbital of the compound A, in units of eV.

In general, the green pigment tends to have low dispersibility, and with regard to coloring compositions including the green pigment, the green pigments tend to aggregate during storage. Therefore, the coloring composition including the green pigment tends to increase in viscosity during storage. However, since the coloring composition according to the embodiment of the present invention includes a predetermined amount of a predetermined compound A, although the coloring composition according to the embodiment of the present invention is a coloring composition including the green pigment, the viscosity thereof does not easily increase even after long-term storage, and storage stability is excellent. The reason for obtaining such an effect is presumed as follows. That is, the coloring composition according to the embodiment of the present invention further includes a predetermined compound A in addition to the green pigment. Since the compound A satisfies the relationship of the expression (a) with the green pigment, the energy level of the lowest unoccupied molecular orbital of the compound A is close to the energy level of the lowest unoccupied molecular orbital of the green pigment, and it is presumed that electron transfer is likely to occur between the green pigment and the compound A. In addition, since this compound A is a compound which is more soluble in propylene glycol methyl ether acetate (hereinafter, also referred to as PGMEA) than the green pigment, it is presumed that the compound A tends to collect in a vicinity of a surface of the green pigment in the coloring composition. Therefore, it is presumed that the compound A is adsorbed in the vicinity of the surface of the green pigment in the coloring composition, and the aggregation of the green pigments can be suppressed. As a result, it is presumed that the viscosity is less likely to increase even after long-term storage, and excellent storage stability is obtained.

In addition, among green pigments, a halogenated phthalocyanine compound particularly tends to have low dispersibility, and a coloring composition including the halogenated phthalocyanine compound as the green pigment tends to increase in viscosity during storage. However, according to the present invention, even in a case where the halogenated phthalocyanine compound is used as the green pigment, by including a predetermined amount of the compound A satisfying the relationship of the expression (a), a coloring composition having excellent storage stability can be obtained. Therefore, the present invention is particularly effective in a case where the halogenated phthalocyanine compound is used as the green pigment.

In addition, since, in the coloring composition according to the embodiment of the present invention, generation of development residue can be suppressed, the present invention is particularly effective in a case of manufacturing a color filter in which a pattern is formed by a photolithography method. Although the detailed reason for obtaining such an effect is unclear, it is presumed that, by adsorbing the compound A on the surface of the green pigment, it is possible to suppress the aggregation of the green pigments even in a film. Therefore, for example, in a case where a coloring composition layer formed by using the coloring composition is patternwise exposed, and then the coloring composition layer in an unexposed area is removed by development, it is presumed that the aggregation of green pigments included in the coloring composition layer in the unexposed area is suppressed, so that permeability or the like of a developer into the coloring composition layer in the unexposed area is good. Therefore, it is presumed that the coloring composition layer in the unexposed area can be efficiently removed by development, and the generation of development residue can be suppressed.

It is preferable that the green pigment and the compound A included in the coloring composition satisfy the relationship of the expression (a1). According to this aspect, the storage stability of the coloring composition can be further improved.

−0.5 eV≤LUMO_{B}−LUMO_{A}≤0.5 eV (a1)

In a case where the coloring composition according to the embodiment of the present invention includes two or more kinds of green pigments, the value of LUMO_{B} in the expression (a) and the expression (a1) is a mass-average value of energy levels of the lowest unoccupied molecular orbitals of the two or more kinds of green pigments. In a case where the coloring composition according to the embodiment of the present invention includes two or more kinds of compounds A, the value of LUMO_{A} in the expression (a) and the expression (a1) is a value of the energy level of the lowest unoccupied molecular orbital of each compound A. Therefore, in the case where the coloring composition according to the embodiment of the present invention includes two or more kinds of compounds A, it is necessary for the energy level of the lowest unoccupied molecular orbital of each compound A to satisfy the relationship of the expression (a) with the energy level of the lowest unoccupied molecular orbital of the green pigment.

The coloring composition according to the embodiment of the present invention can be preferably used as a green coloring composition or a cyan coloring composition, and can be more preferably used as a cyan coloring composition. In addition, the coloring composition according to the embodiment of the present invention can be preferably used as a coloring composition for forming a pixel of a color filter, can be more preferably used as a coloring composition for forming a green pixel or cyan pixel of a color filter, and can be still more preferably used as a coloring composition for forming a cyan pixel. In addition, the coloring composition according to the embodiment of the present invention can also be used as a composition for forming a color microlens. Examples of a method for manufacturing the color microlens include the method described in JP2018-010162A.

Hereinafter, the respective components used in the coloring composition according to the embodiment of the present invention will be described.

“Colorant”

The coloring composition according to the embodiment of the present invention contains a colorant. The colorant included in the coloring composition according to the embodiment of the present invention includes a green pigment.

The amount of the green pigment dissolved in 100 g of propylene glycol methyl ether acetate at 25° C. is less than 0.01 g, preferably 0.005 g or less, more preferably 0.001 g or less, and still more preferably 0.0001 g or less. In a case where the above-described amount of the green pigment dissolved is less than 0.01 g, dispersion stability is good. The lower limit of the dissolved amount is not particularly limited, but may be, for example, 0.00001 g or more.

The energy level of the lowest unoccupied molecular orbital of the green pigment is preferably −5.5 to −3.5 eV. The upper limit is preferably −3.6 eV or less, more preferably −3.8 eV or less, and still more preferably −4.1 eV or less. The lower limit is preferably −5.4 eV or more, more preferably −5.2 eV or more, and still more preferably −4.9 eV or more.

The energy level of the highest occupied molecular orbital of the green pigment is preferably −7.0 to −4.5 eV. The upper limit is preferably −4.6 eV or less, more preferably −5.0 eV or less, and still more preferably −5.5 eV or less. The lower limit is preferably −6.9 eV or more, more preferably −6.5 eV or more, and still more preferably −6.0 eV or more.

The absolute value of the difference between the energy level of the lowest unoccupied molecular orbital of the green pigment and the energy level of the highest occupied molecular orbital of the green pigment is preferably 0 to 4.0 eV, more preferably 1.5 to 3.0 eV, and still more preferably 2.2 to 2.8 eV.

The specific absorbance of the green pigment at a maximum absorption wavelength of 450 to 800 nm, which is represented by the following expression (A_{λ2}), is preferably 20 or more, more preferably 40 or more, and still more preferably 50 or more.

E²=A²/(c²×l²) (A_{λ2})

In the expression (A_{λ2}), E² represents the specific absorbance of the green pigment at the maximum absorption wavelength of 450 to 800 nm, A² represents an absorbance of the green pigment at the maximum absorption wavelength of 450 to 800 nm, l² represents a cell length in units of cm, and c² represents a concentration of the green pigment in a solution, in units of mg/ml.

Examples of a method for measuring the specific absorbance of the green pigment include a method in which, using a solvent having sufficient solubility with the green pigment, the concentration of a solution including the green pigment is adjusted such that the maximum absorbance at 450 to 800 nm is 1.0, and then the absorbance of the solution at 25° C. is measured using a cell having an optical path length of 1 cm. As the solvent for measuring the specific absorbance, a solvent having sufficient solubility with the green pigment can be appropriately used. Examples thereof include methanesulfonic acid.

Examples of compound species of the green pigment include phthalocyanine compounds and squarylium compounds, and from the reason that the effects of the present invention can be obtained more remarkably, a phthalocyanine compound is preferable and a halogenated phthalocyanine compound is more preferable. The halogenated phthalocyanine compound is a phthalocyanine compound having one or more halogen atoms in the molecule. Examples of the halogenated phthalocyanine compound include a compound represented by Formula (Pc1).

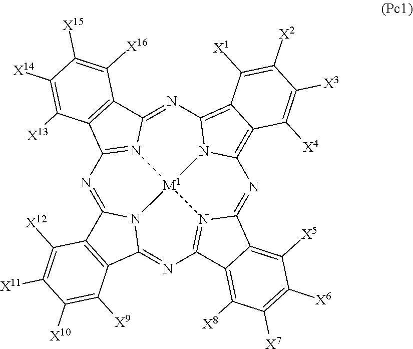

In Formula (Pc1), X¹ to X¹⁶ each independently represent a hydrogen atom or a substituent, and M¹ represents a zinc atom, a copper atom, an aluminum atom, or a vanadium atom. However, at least one of X¹ to X¹⁶ represents a halogen atom.

Examples of the substituent represented by X¹ to X¹⁶ include the substituent T described later. Examples of the halogen atom represented by at least one of X¹ to X¹⁶ include a chlorine atom, a bromine atom, a fluorine atom, and an iodine atom, and a bromine atom or a chlorine atom is preferable.

It is preferable that X¹ to X¹⁶ each independently represent a hydrogen atom or a halogen atom. In addition, it is preferable that any 8 to 16 places of X¹ to X¹⁶ are halogen atoms and the rest are hydrogen atoms.

(Substituent T)

Examples of a substituent T include a halogen atom, a cyano group, a nitro group, an alkyl group, an aryl group, a heterocyclic group, —ORt¹, —CORt¹, —COORt¹, —OCORt¹, —NRt¹Rt². —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Rt¹ and Rt² each independently represent a hydrogen atom, an alkyl group, an aryl group, or a heterocyclic group. Rt¹ and Rt² may be bonded to each other to form a ring.

Examples of the halogen atom include a fluorine atom, a chlorine atom, a bromine atom, and an iodine atom.

The alkyl group preferably has 1 to 30 carbon atoms, more preferably has 1 to 15 carbon atoms, and still more preferably has 1 to 8 carbon atoms. The alkyl group may be linear, branched, or cyclic, and is preferably linear or branched and more preferably linear.

The number of carbon atoms in the aryl group is preferably 6 to 30, more preferably 6 to 20, and still more preferably 6 to 12.

The heterocyclic group may be a monocyclic ring or a fused ring. The heterocyclic group is preferably a monocyclic ring or a fused ring having 2 to 4 fused rings. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

The alkyl group, the aryl group, and the heterocyclic group may have a substituent or may be unsubstituted. Examples of the substituent include the substituent described in the substituent T.

Specific examples of the green pigment include phthalocyanine compounds such as Color Index (C. I.) Pigment Green 7, 10, 36, 37, 58, 59, 62, and 63. In addition, as the green pigment, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used.

Specific examples thereof include the compounds described in WO2015/118720A. In addition, as the green pigment, a compound described in CN2010-6909027A, a phthalocyanine compound described in WO2012/102395A, which has phosphoric acid ester as a ligand, a phthalocyanine compound described in JP2019-008014A, a phthalocyanine compound described in JP2018-180023A, and the like can also be used.

(Other Colorants)

The coloring composition according to the embodiment of the present invention can further contain a colorant having a color tone other than green. Examples of the other colorants include yellow colorants, orange colorants, red colorants, violet colorants, and blue colorants. The other colorants may be either a pigment or a dye.

As the pigment, an organic pigment is preferable. In addition, the average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the coloring composition is good. In the present invention, the primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is the arithmetic average value of the primary particle diameters with respect to 400 primary particles of the pigment. In addition, the primary particle of the pigment refers to a particle which is independent without aggregation.

The coloring composition according to the embodiment of the present invention preferably includes a yellow colorant as the other colorants, and more preferably includes a yellow pigment. According to this aspect, it is possible to suppress occurrence of aggregation, precipitation, or the like of the green pigment during film formation and the like. Furthermore, it is easy to form a film having spectral characteristics suitable for green pixels.

Examples of the yellow pigment include an azo compound, an isoindolinone compound, an isoindoline compound, a quinophthalone compound, and an anthraquinone compound, and an isoindoline compound or a quinophthalone compound is preferable, and an isoindoline compound is more preferable.

Specific examples of the yellow pigment include Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), and 233 (quinoline-based).

In addition, as the yellow colorant, compounds described in JP2017-201003A, compounds described in JP2017-197719A, compounds described in paragraphs “0011” to “0062” and “0137” to “0276” of JP2017-171912A, compounds described in paragraphs “0010” to “0062” and “0138” to “0295” of JP2017-171913A, compounds described in paragraphs “0011” to “0062” and “0139” to “0190” of JP2017-171914A, compounds described in paragraphs “0010” to “0065” and “0142” to “0222” of JP2017-171915A, quinophthalone compounds described in paragraphs “0011” to “0034” of JP2013-054339A, quinophthalone compounds described in paragraphs “0013” to “0058” of JP2014-026228A, isoindoline compounds described JP2018-062644A, quinophthalone compounds described in JP2018-203798A, quinophthalone compounds described in JP2018-062578A, quinophthalone compounds described in JP6432077B, quinophthalone compounds described in JP6432076B, quinophthalone compounds described in JP2018-155881A, quinophthalone compounds described in JP2018-111757A, quinophthalone compounds described in JP2018-040835A, quinophthalone compounds described in JP2017-197640A, quinophthalone compounds described in JP2016-145282A, quinophthalone compounds described in JP2014-085565A, quinophthalone compounds described in JP2014-021139A, quinophthalone compounds described in JP2013-209614A, quinophthalone compounds described in JP2013-209435A, quinophthalone compounds described in JP2013-181015A, quinophthalone compounds described in JP2013-061622A, quinophthalone compounds described in JP2013-054339A, quinophthalone compounds described in JP2013-032486A, quinophthalone compounds described in JP2012-226110A, quinophthalone compounds described in JP2008-074987A, quinophthalone compounds described in JP2008-081565A, quinophthalone compounds described in JP2008-074986A, quinophthalone compounds described in JP2008-074985A, quinophthalone compounds described in JP2008-050420A, quinophthalone compounds described in JP2008-031281A, quinophthalone compounds described in JP1973-032765A (JP-S48-032765A), quinophthalone compounds described in JP2019-008014A, a compound represented by Formula (QP1), and a compound represented by Formula (QP2) can also be used.

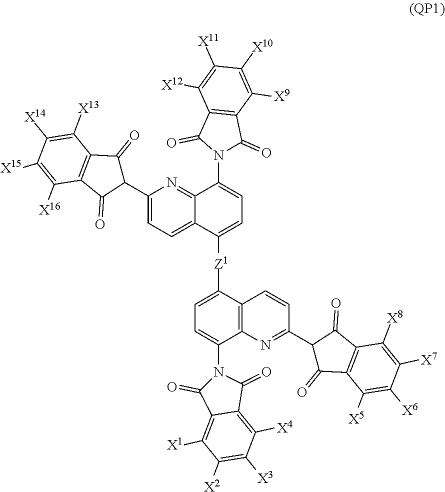

In Formula (QP1), X¹ to X¹⁶ each independently represent a hydrogen atom or a halogen atom, and Z¹ represents an alkylene group having 1 to 3 carbon atoms. Specific examples of the compound represented by Formula (QP1) include compounds described in paragraph “0016” of JP6443711B.

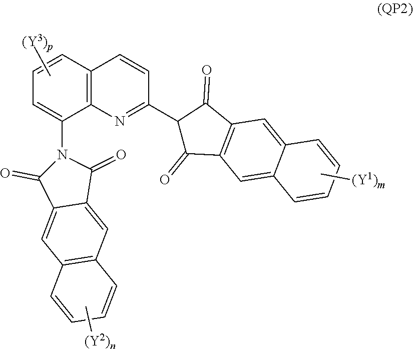

In Formula (QP2), Y¹ to Y³ each independently represent a halogen atom, n and m represent an integer of 0 to 6, and p represents an integer of 0 to 5. (n+m) is 1 or more.

Specific examples of the compound represented by Formula (QP2) include compounds described in paragraphs “0047” and “0048” of JP6432077B.

Examples of chromatic colorants other than yellow include the following.

C. I. Pigment Orange 2, 5, 13, 16, 17:1, 31, 34, 36, 38, 43, 46, 48, 49, 51, 52, 55, 59, 60, 61, 62, 64, 71, 73, and the like (all of which are orange pigments); C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (monoazo-based), 296 (diazo-based), and the like (all of which are red pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, as the blue pigment, an aluminum phthalocyanine compound having a phosphorus atom can also be used. Specific examples thereof include compounds described in paragraphs “0022” to “0030” of JP2012-247591A and paragraph “0047” of JP2011-157478A.

As the red pigment, diketopyrrolopyrrole-based pigments described in JP2017-201384A, in which the structure has at least one substituted bromine atom, diketopyrrolopyrrole-based pigments described in paragraphs “0016” to “0022” of JP6248838B, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As such a compound, a compound represented by Formula (DPP1) is preferable, and a compound represented by Formula (DPP2) is more preferable.

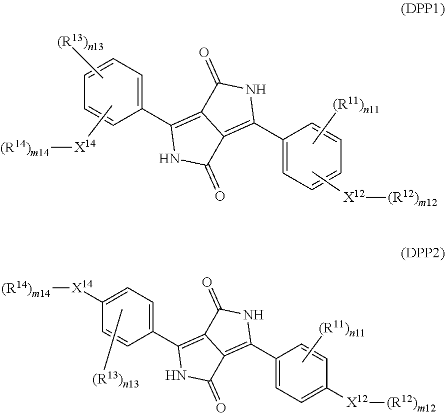

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Examples of the substituent represented by R¹¹ and R¹³ include the groups in the above-described substituent T, and preferred specific examples thereof include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

As the dye, a known dye can be used without any particular limitation. Examples thereof include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound.

In addition, as the other colorants, thiazole compounds described in JP2012-158649A, azo compounds described in JP2011-184493A, or azo compounds described in JP2011-145540A can also be used.

The content of the colorant in the total solid content of the coloring composition is preferably 20 mass % or more, more preferably 30 mass % or more, still more preferably 40 mass % or more, and particularly preferably 45 mass % or more. In general, as the content of the colorant increases, the storage stability of the coloring composition tends to decrease. However, the coloring composition according to the embodiment of the present invention has excellent storage stability even in a case where the content of the colorant is large. Therefore, the effect of the present invention can be remarkably obtained in a case where the content of the colorant is large. The upper limit of the content of the colorant in the total solid content of the coloring composition is preferably 80 mass % or less, more preferably 75 mass % or less, still more preferably 70 mass % or less, and particularly preferably 65 mass % or less.

The content of the green pigment in the total solid content of the coloring composition is preferably 10 mass % or more, more preferably 20 mass % or more, still more preferably 30 mass % or more, and particularly preferably 35 mass % or more. The upper limit is preferably 70 mass % or less, more preferably 65 mass % or less, still more preferably 60 mass % or less, and particularly preferably 55 mass % or less.

In addition, the content of the green pigment in the colorant used in the coloring composition according to the embodiment of the present invention is preferably 40 mass % or more, more preferably 50 mass % or more, and still more preferably 60 mass % or more. The upper limit may be 100 mass %, 90 mass % or less, or 80 mass % or less.

In addition, the proportion of the phthalocyanine compound in the green pigment is preferably 50 mass % or more and more preferably 70 mass % or more, and it is still more preferable that the green pigment is substantially composed of the phthalocyanine compound alone. The case where the green pigment is substantially composed of the phthalocyanine compound alone means that the proportion of the phthalocyanine compound in the total amount of the green pigment is 99 mass % or more, preferably 99.5 mass % or more, and it is still more preferable that the green pigment is composed of the phthalocyanine compound alone.

The content of the yellow pigment in the total solid content of the coloring composition is preferably 1 mass % or more, more preferably 3 mass % or more, and still more preferably 5 mass % or more. The upper limit is preferably 30 mass % or less, more preferably 20 mass % or less, and still more preferably 15 mass % or less.

In addition, the total content of the green pigment and yellow pigment in the colorant used in the coloring composition according to the embodiment of the present invention is preferably 45 to 100 mass %, more preferably 50 to 100 mass %, and still more preferably 55 to 100 mass %.

In a case where the coloring composition according to the embodiment of the present invention is used as a coloring composition for forming a green pixel, the mass ratio of the green pigment and the yellow pigment is preferably 90/10 to 40/60 and more preferably 85/15 to 60/40.

In a case where the coloring composition according to the embodiment of the present invention is used as a coloring composition for forming a cyan pixel, the mass ratio of the green pigment and the yellow pigment is preferably 100/0 to 80/20 and more preferably 100/0 to 90/10.

“Compound A”

The coloring composition according to the embodiment of the present invention includes a compound A which satisfies the relationship of the above-described expression (a) (preferably, the relationship of the above-described expression (a1)) with the green pigment included in the coloring composition.

The amount of the compound A dissolved in 100 g of propylene glycol methyl ether acetate at 25° C. is 0.01 g or more, preferably 0.05 g or more and more preferably 0.1 g or more.

In a case where the above-described amount of the compound A dissolved is 0.01 g or more, it is presumed that the compound A is efficiently adsorbed on the green pigment in the coloring composition, so that the storage stability of the coloring composition can be improved. The upper limit of the above-described dissolved amount is preferably less than 1.0 g. In a case where the above-described amount of the compound A dissolved is less than 1.0 g, it is presumed that the compound A is more efficiently adsorbed on the green pigment in the coloring composition, so that the storage stability of the coloring composition can be further improved.

In addition, the difference between the amount of the compound A dissolved in 100 g of propylene glycol methyl ether acetate at 25° C. and the amount of the green pigment dissolved in 100 g of propylene glycol methyl ether acetate at 25° C. is preferably 0.1 g or more. According to this aspect, since the compound A tends to be in an equilibrium state in which a part of the compound A is adsorbed on the green pigment and a part of the compound A is dissolved in the solvent, the storage stability of the coloring composition is further improved.

The energy level of the lowest unoccupied molecular orbital of the compound A is preferably −6.0 to −3.0 eV. The upper limit is preferably −3.9 eV or less, more preferably −4.2 eV or less, and still more preferably −4.5 eV or less. The lower limit is preferably −5.5 eV or more, more preferably −5.2 eV or more, and still more preferably −4.9 eV or more. In a case where the energy level of the lowest unoccupied molecular orbital of the compound A is within the above-described range, dispersion stability of the green pigment is more excellent.

The energy level of the highest occupied molecular orbital of the compound A is preferably −8.0 to −4.5 eV. The upper limit is preferably −5.0 eV or less, more preferably −5.5 eV or less, and still more preferably −6.0 eV or less. The lower limit is preferably −7.5 eV or more, more preferably −7.0 eV or more, and still more preferably −6.5 eV or more. In a case where the energy level of the highest occupied molecular orbital of the compound A is within the above-described range, the dispersion stability of the green pigment is more excellent.

The specific absorbance of the compound A at a maximum absorption wavelength of 450 to 800 nm, which is represented by the following expression (A_{λ1}), is preferably 50 or less, more preferably 30 or less, and still more preferably 10 or less. According to this aspect, the storage stability of the coloring composition can be more effectively improved without impairing spectral characteristics of the green pigment. In addition, the specific absorbance of the compound A at a maximum absorption wavelength of 450 to 800 nm, which is represented by the following expression (A_{λ1}), is preferably 1.0 or more, more preferably 3.0 or more, and still more preferably 5.0 or more.

E¹=A¹/(c¹×l¹) (A_{λ1})

In the expression (A_{λ1}), E¹ represents the specific absorbance of the compound A at the maximum absorption wavelength of 450 to 800 nm, A¹ represents an absorbance of the compound A at the maximum absorption wavelength of 450 to 800 nm, l¹ represents a cell length in units of cm, and c¹ represents a concentration of the compound A in a solution, in units of mg/ml.

Examples of a method for measuring the specific absorbance of the compound A include a method in which, using a solvent having sufficient solubility with the compound A, the concentration of a solution including the compound A is adjusted such that the maximum absorbance at 450 to 800 nm is 1.0, and then the absorbance of the solution at 25° C. is measured using a cell having an optical path length of 1 cm. As the solvent for measuring the specific absorbance, a solvent having sufficient solubility with the compound A can be appropriately used. Examples thereof include tetrahydrofuran, toluene, and dimethylacetamide.

The compound A is preferably a compound represented by any of Formula (1) to Formula (7), and from the reason that the compound has high leveling and is more easily adsorbed on the green pigment, the compound A is more preferably a compound represented by Formula (1).

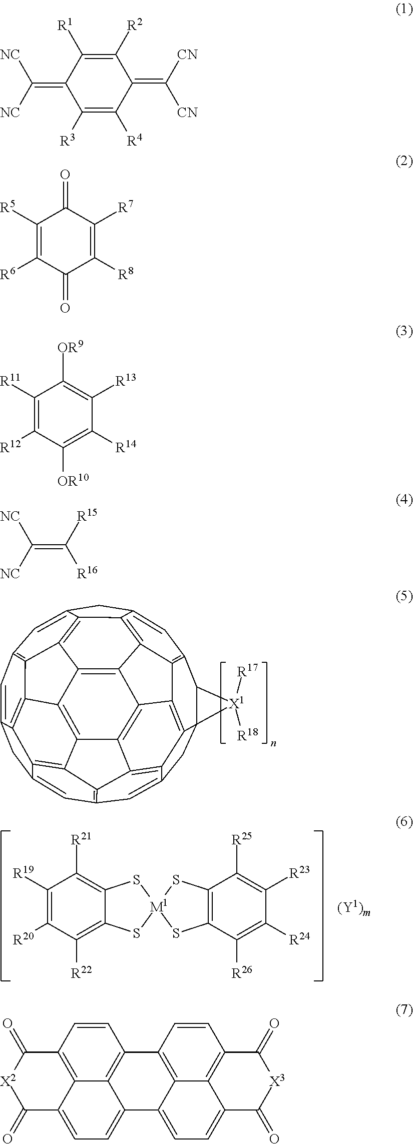

In Formula (1), R¹ to R⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R¹ and R², or R³ and R⁴ may be bonded to each other to form a ring;

in Formula (2), R⁵ to R⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R⁵ and R⁶, or R⁷ and R⁸ may be bonded to each other to form a ring;

in Formula (3), R⁹ and R¹⁰ each independently represent a hydrogen atom, a hydrocarbon group, or a heterocyclic group, R¹¹ to R¹⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹¹ and R¹², or R¹³ and R¹⁴ may be bonded to each other to form a ring;

in Formula (4), R¹⁵ and R¹⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁵ and R¹⁶ may be bonded to each other to form a ring;

in Formula (5), X¹ represents a carbon atom or a silicon atom, n represents an integer of 1 to 5, R¹⁷ and R¹⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁷ and R¹⁸ may be bonded to each other to form a ring;

in Formula (6), M¹ represents a metal atom, R¹⁹ to R²⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, R¹⁹ and R²¹, R¹⁹ and R²⁰, R²⁰ and R²², R²³ and R²⁵, R²³ and R²⁴, or R²⁴ and R²⁶ may be bonded to each other to form a ring, in a case where a moiety enclosed in [ ] in the formula is a cationic moiety, Y¹ represents a counter anion and m represents the number required to balance charges, in a case where a moiety enclosed in [ ] in the formula is an anionic moiety, Y¹ represents a counter cation and m represents the number required to balance charges, and in a case where a charge of a moiety enclosed in [ ] in the formula is neutralized in the molecule, m is 0; and

in Formula (7), X² and X³ each independently represent O or NRx, where Rx represents a hydrogen atom or a substituent.

[Regarding Formula (1)]

In Formula (1), R¹ to R⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R¹ and R², or R³ and R⁴ may be bonded to each other to form a ring.

Examples of the hydrocarbon group of R¹ to R⁴ in Formula (1) include an aliphatic hydrocarbon group and an aromatic hydrocarbon group. The aliphatic hydrocarbon group may be a saturated aliphatic hydrocarbon group or an unsaturated aliphatic hydrocarbon group. In addition, the aliphatic hydrocarbon group may be a chain-like aliphatic hydrocarbon group or a cyclic aliphatic hydrocarbon group. Specific examples of the hydrocarbon group include an alkyl group, an alkenyl group, an alkynyl group, and an aryl group.

The number of carbon atoms in the alkyl group is preferably 1 to 40, more preferably 1 to 30, still more preferably 1 to 20, and particularly preferably 1 to 10. The alkyl group may be linear, branched, or cyclic, and is preferably linear or branched and more preferably linear.

The number of carbon atoms in the alkenyl group and the alkynyl group is preferably 2 to 40, more preferably 2 to 30, still more preferably 2 to 20, and particularly preferably 2 to 10. The alkenyl group and the alkynyl group may be linear, branched, or cyclic, and is preferably linear or branched and more preferably linear.

The number of carbon atoms in the aryl group is preferably 6 to 30, more preferably 6 to 20, and still more preferably 6 to 12.

The heterocyclic group of R¹ to R⁴ in Formula (1) may be a monocyclic ring or a fused ring. The heterocyclic group may be an aromatic heterocyclic group or a non-aromatic heterocyclic group. The number of heteroatoms constituting a ring of the heterocyclic group is preferably 1 to 3. The heteroatom constituting the ring of the heterocyclic group is preferably a nitrogen atom, an oxygen atom, or a sulfur atom. The number of carbon atoms constituting the ring of the heterocyclic group is preferably 3 to 30, more preferably 3 to 18, and more preferably 3 to 12.

Examples of the halogen atom of R¹ to R⁴ in Formula (1) include a fluorine atom, a chlorine atom, a bromine atom, and an iodine atom.

The number of carbon atoms in the alkoxy group of R¹ to R⁴ in Formula (1) is preferably 1 to 40, more preferably 1 to 30, still more preferably 1 to 20, and particularly preferably 1 to 10. The alkoxy group may be linear, branched, or cyclic, and is preferably linear or branched and more preferably linear.

The number of carbon atoms in the aryloxy group of R¹ to R⁴ in Formula (1) is preferably 6 to 30, more preferably 6 to 20, and still more preferably 6 to 12.

The number of carbon atoms in the alkylcarbonyl group of R¹ to R⁴ in Formula (1) is preferably 2 to 40, more preferably 2 to 30, still more preferably 2 to 20, and particularly preferably 2 to 10. The alkylcarbonyl group may be linear, branched, or cyclic, and is preferably linear or branched and more preferably linear.

The number of carbon atoms in the arylcarbonyl group of R¹ to R⁴ in Formula (1) is preferably 7 to 30, more preferably 7 to 20, and still more preferably 7 to 12.

The number of carbon atoms in the alkoxy carbonyl group of R¹ to R⁴ in Formula (1) is preferably 2 to 40, more preferably 2 to 30, still more preferably 2 to 20, and particularly preferably 2 to 10. The alkoxy carbonyl group may be linear, branched, or cyclic, and is preferably linear or branched and more preferably linear.

The number of carbon atoms in the aryloxy carbonyl group of R¹ to R⁴ in Formula (1) is preferably 7 to 30, more preferably 7 to 20, and still more preferably 7 to 12.

The number of carbon atoms in the alkylthio group of R¹ to R⁴ in Formula (1) is preferably 1 to 40, more preferably 1 to 30, still more preferably 1 to 20, and particularly preferably 1 to 10. The alkylthio group may be linear, branched, or cyclic, and is preferably linear or branched and more preferably linear.

The number of carbon atoms in the arylthio group of R¹ to R⁴ in Formula (1) is preferably 6 to 30, more preferably 6 to 20, and still more preferably 6 to 12.

Examples of the amino group of R¹ to R⁴ in Formula (1) include an unsubstituted amino group (—NH₂), a monoalkylamino group, a dialkylamino group, a monoarylamino group, a diarylamino group, and an alkylarylamino group. Specific examples of the amino group include —NH₂, an N-methylamino group, an N-ethylamino group, an N,N-diethylamino group, an N,N-diisopropylamino group, an N,N-dibutylamino group, an N-benzylamino group, an N,N-dibenzylamino group, an N-phenylamino group, an N-phenyl-N-methylamino group, an N,N-diphenylamino group, an N,N-bis(m-tolyl)amino group, an N,N-bis(p-tolyl)amino group, an N,N-bis(p-biphenylyl)amino group, a bis[4-(4-methyl)biphenylyl]amino group, an N-α-naphthyl-N-phenylamino group, and an N-β-naphthyl-N-phenylamino group.

Examples of the silyl group of R¹ to R⁴ in Formula (1) include an unsubstituted silyl group, a monoalkylsilyl group, a monoarylsilyl group, a dialkylsilyl group, a diarylsilyl group, a trialkylsilyl group, a triarylsilyl group. Examples of the monoalkylsilyl group include a monomethylsilyl group, a monoethylsilyl group, a monobutylsilyl group, a monoisopropylsilyl group, a monodecanesilyl group, a monoicosanesilyl group, and a monotriacontanesilyl group. Examples of the monoarylsilyl group include a monophenylsilyl group, a monotolylsilyl group, a mononaphthylsilyl group, and a monoanthrylsilyl group. Examples of the dialkylsilyl group include a dimethylsilyl group, a diethylsilyl group, a dimethylethylsilyl group, a diisopropylsilyl group, a dibutylsilyl group, a dioctylsilyl group, and a didecanesilyl group. Examples of the diarylsilyl group include a diphenylsilyl group and a ditolylsilyl group. Examples of the trialkylsilyl group include a trimethylsilyl group, a triethylsilyl group, a trimethylethylsilyl group, a triisopropylsilyl group, a tributylsilyl group, and a trioctylsilyl group. Examples of the triarylsilyl group include a triphenylsilyl group and a tritolylsilyl group.

Examples of the phosphino group of R¹ to R⁴ in Formula (1) include an unsubstituted phosphino group, a monoalkyl phosphino group, a monoaryl phosphino group, a dialkyl phosphino group, and a diaryl phosphino group. Examples of the monoalkyl phosphino group include a monomethyl phosphino group, a monoethyl phosphino group, a monobutyl phosphino group, a monoisopropyl phosphino group, and a monodecane phosphino group. Examples of the monoaryl phosphino group include a monophenyl phosphino group, a monotolyl phosphino group, a mononaphthyl phosphino group, and a monopyrenyl phosphino group. Examples of the dialkyl phosphino group include a dimethyl phosphino group, a diethyl phosphino group, a dimethylethyl phosphino group, a diisopropyl phosphino group, a dibutyl phosphino group, a dioctyl phosphino group, and a didecane phosphino group. Examples of the diaryl phosphino group include a diphenyl phosphino group, a ditolyl phosphino group, a dinaphthyl phosphino group, and a pyrenylphenyl phosphino group.

In a case where the above-described groups represented by R¹ to R⁴ are groups capable of further having a substituent, the above-described groups may further have a substituent. Examples of the further substituent include a hydrocarbon group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group. The details of these groups are synonymous in ranges described in R¹ to R⁴.

In Formula (1), R¹ and R², or R³ and R⁴ may be bonded to each other to form a ring. The ring formed by bonding these groups to each other may be an aliphatic ring, an aromatic ring, or a heterocyclic ring. The ring formed by bonding these groups to each other may have a substituent. Examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group. The details of these groups are synonymous in ranges described in R¹ to R⁴.

R¹ to R⁴ in Formula (1) is preferably a hydrogen atom, a halogen atom, an alkoxy group, or an alkyl group, more preferably a hydrogen atom, a halogen atom, or an alkoxy group, and from the reason that it is easy to set the energy level of the lowest unoccupied molecular orbital closer to that of the green pigment, still more preferably a hydrogen atom or a halogen atom.

[Regarding Formula (2)]

In Formula (2), R⁵ to R⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R⁵ and R⁶, or R⁷ and R⁸ may be bonded to each other to form a ring. The details of these groups represented by R⁵ to R⁸ are synonymous in ranges described in Formula (1).

In Formula (2), R⁵ and R⁶, or R⁷ and R⁸ may be bonded to each other to form a ring. The ring formed by bonding these groups to each other may be an aliphatic ring, an aromatic ring, or a heterocyclic ring. The ring formed by bonding these groups to each other may have a substituent. Examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group. The details of these groups are synonymous in ranges described in R¹ to R⁴.

Examples of the preferred aspects of Formula (2) include the following aspects (2-1) to (2-3).

(2-1): aspect in which R⁵ to R⁸ are each independently a halogen atom, a cyano group, or a nitro group (preferably, a halogen atom or a cyano group).

(2-2): aspect in which R⁵ and R⁶ are bonded to each other to form a ring (preferably, an aromatic ring), and R⁷ and R⁸ are each independently a halogen atom, a cyano group, or a nitro group (preferably, a halogen atom or a cyano group); in this aspect, the ring formed by bonding R⁵ and R⁶ to each other may have a substituent; examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group, and a halogen atom, an alkoxy group, a cyano group, a nitro group, or an amino group is preferable and a halogen atom or an alkoxy group is more preferable.

(2-3): aspect in which R⁵ and R⁶ are bonded to each other to form a ring (preferably, an aromatic ring), and R⁷ and R⁸ are bonded to each other to form a ring (preferably, an aromatic ring); in this aspect, the ring formed by bonding R⁵ and R⁶ to each other and the ring formed by bonding R⁷ and R⁸ to each other may have a substituent; examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group, and a halogen atom, an alkoxy group, a cyano group, a nitro group, or an amino group is preferable and a halogen atom or an alkoxy group is more preferable.

[Regarding Formula (3)]

In Formula (3), R⁹ and R¹⁰ each independently represent a hydrogen atom, a hydrocarbon group, or a heterocyclic group, R¹¹ to R¹⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹¹ and R¹², or R¹³ and R¹⁴ may be bonded to each other to form a ring. The details of these groups represented by R⁹ to R¹⁴ are synonymous in ranges described in Formula (1).

In Formula (3), R⁹ and R¹⁰ are each independently preferably a hydrogen atom or a hydrocarbon group and more preferably a hydrogen atom.

In Formula (3), R¹¹ and R¹², or R¹³ and R¹⁴ may be bonded to each other to form a ring. The ring formed by bonding these groups to each other may be an aliphatic ring, an aromatic ring, or a heterocyclic ring. The ring formed by bonding these groups to each other may have a substituent. Examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group. The details of these groups are synonymous in ranges described in R¹ to R⁴.

Examples of the preferred aspects of R¹¹ to R¹⁴ in Formula (3) include the following aspects (3-1) to (3-3).

(3-1): aspect in which R¹¹ to R¹⁴ are each independently a halogen atom, a cyano group, or a nitro group (preferably, a halogen atom or a cyano group).

(3-2): aspect in which R¹¹ and R¹² are bonded to each other to form a ring (preferably, an aromatic ring), and R¹³ and R¹⁴ are each independently a halogen atom, a cyano group, or a nitro group (preferably, a halogen atom or a cyano group); in this aspect, the ring formed by bonding R¹¹ and R¹² to each other may have a substituent; examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group, and a halogen atom, a cyano group, a nitro group, or an amino group is preferable.

(3-3): aspect in which R¹¹ and R¹² are bonded to each other to form a ring (preferably, an aromatic ring), and R¹³ and R¹⁴ are bonded to each other to form a ring (preferably, an aromatic ring); in this aspect, the ring formed by bonding R¹¹ and R¹² to each other and the ring formed by bonding R¹³ and R¹⁴ to each other may have a substituent; examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group, and a halogen atom, an alkoxy group, a cyano group, a nitro group, or an amino group is preferable and a halogen atom or an alkoxy group is more preferable.

[Regarding Formula (4)]

In Formula (4), R¹⁵ and R¹⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁵ and R¹⁶ may be bonded to each other to form a ring. The details of these groups represented by R¹⁵ and R¹⁶ are synonymous in ranges described in Formula (1).

In Formula (4), it is preferable that R¹⁵ and R¹⁶ are bonded to each other to form a ring. The formed ring may be an aliphatic ring, an aromatic ring, or a heterocyclic ring, but an aromatic ring is preferable, an aromatic ring of a fused ring is more preferable, and an aromatic ring having a ring structure of 3 or more rings is still more preferable. Examples of the aromatic ring having a ring structure of 3 or more rings include a fluorene ring. The ring formed by bonding R¹⁵ and R¹⁶ to each other may have a substituent. Examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group, and a halogen atom, an alkoxy group, a cyano group, a nitro group, or an amino group is preferable and a nitro group, a halogen atom, or an alkoxy group is more preferable.

Formula (4) is preferably a structure represented by Formula (4a).

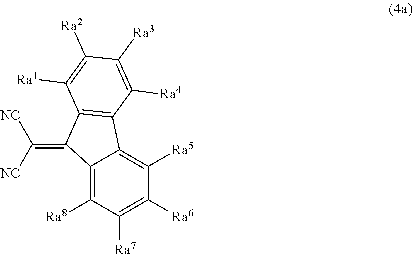

In Formula (4a), Ra¹ to Ra⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group. Ra¹ and Ra², Ra² and Ra³, Ra³ and Ra⁴, Ra⁵ and Ra⁶, Ra⁶ and Ra⁷, or Ra⁷ and Ra⁸ may be bonded to each other to form a ring. The details of these groups represented by Ra¹ to Ra⁸ are synonymous in ranges described in Formula (1).

[Regarding Formula (5)]

In Formula (5), X¹ represents a carbon atom or a silicon atom, n represents an integer of 1 to 5, R¹⁷ and R¹⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R¹⁷ and R¹⁸ may be bonded to each other to form a ring. The details of these groups represented by R¹⁷ and R¹⁸ are synonymous in ranges described in Formula (1).

In Formula (5), R¹⁷ and R¹⁸ may be bonded to each other to form a ring. The ring formed by bonding these groups to each other may be an aliphatic ring, an aromatic ring, or a heterocyclic ring. The ring formed by bonding these groups to each other may have a substituent. Examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group. The details of these groups are synonymous in ranges described in R¹ to R⁴.

X¹ is preferably a carbon atom, n is preferably 1 to 3, more preferably 1 or 2, and still more preferably 1. R¹⁷ and R¹⁸ are each independently preferably a hydrocarbon group, an alkoxy group, or an alkoxycarbonyl group, more preferably a hydrocarbon group or an alkoxycarbonyl group, and still more preferably a hydrocarbon group. Among these, it is preferable that one of R¹⁷ or R¹⁸ is an aryl group and the other is an alkyl group. The aryl group may have a substituent, and but preferably does not have a substituent. The alkyl group preferably has a substituent. Examples of the substituent include a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group, and an alkoxycarbonyl group or an aryloxycarbonyl group is preferable and an alkoxycarbonyl group is more preferable. The details of these groups are synonymous in ranges described in Formula (1).

[Regarding Formula (6)]

In Formula (6), M¹ represents a metal atom, R¹⁹ to R²⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, R¹⁹ and R²¹, R¹⁹ and R²⁰, R²⁰ and R²², R²³ and R²⁵, R²³ and R²⁴, or R²⁴ and R²⁶ may be bonded to each other to form a ring, in a case where a moiety enclosed in [ ] in the formula is a cationic moiety, Y¹ represents a counter anion and m represents the number required to balance charges, in a case where a moiety enclosed in [ ] in the formula is an anionic moiety, Y¹ represents a counter cation and m represents the number required to balance charges, and in a case where a charge of a moiety enclosed in [ ] in the formula is neutralized in the molecule, m is 0.

The details of the above-described groups represented by R¹⁹ to R²⁶ are synonymous in ranges described in Formula (1). It is preferable that R¹⁹ to R²⁶ each independently represent a hydrogen atom, a halogen atom, an alkoxy group, or an amino group (preferably, a halogen atom or an alkoxy group), and at least one of R¹⁹, R²⁰, R²¹, or R²² and at least one of R²³, R²⁴, R²⁵, or R²⁶ each independently represent a halogen atom, an alkoxy group, or an amino group (preferably, a halogen atom or an alkoxy group).

Examples of the metal atom represented by M¹ include nickel, platinum, copper, and zinc, and nickel is preferable.

In Formula (6), R¹⁹ and R²¹, R¹⁹ and R²⁰, R²⁰ and R²², R²³ and R²⁵, R²³ and R²⁴, or R²⁴ and R²⁶ may be bonded to each other to form a ring. The ring formed by bonding these groups to each other may be an aliphatic ring, an aromatic ring, or a heterocyclic ring. The ring formed by bonding these groups to each other may have a substituent. Examples of the substituent include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, and a phosphino group. The details of these groups are synonymous in ranges described in R¹ to R⁴.

In Formula (6), in a case where a moiety enclosed in [ ] in the formula is a cationic moiety, Y¹ represents a counter anion and m represents the number required to balance charges, in a case where a moiety enclosed in [ ] in the formula is an anionic moiety, Y¹ represents a counter cation and m represents the number required to balance charges, and in a case where a charge of a moiety enclosed in [ ] in the formula is neutralized in the molecule, m is 0. Examples of the counter anion include a hydroxide ion, a halide ion, an alkylcarboxylic acid ion, an arylcarboxylic acid ion, an alkylsulfonic acid ion, an arylsulfonic acid ion, an aryldisulfonic acid ion, an alkylsulfate ion, a sulfate ion, a thiocyanic acid ion, a nitrate ion, a perchlorate ion, a borate ion, a sulfonate ion, an imide ion, a phosphate ion, a hexafluorophosphate ion, a picric acid ion, an amide ion (including amide substituted with an acyl group or a sulfonyl group), and a methide ion (including methide substituted with an acyl group or a sulfonyl group). Examples of the counter cation include ammonium ions (for example, a tetraalkylammonium ion such as a tetrabutylammonium ion, a triethylbenzylammonium ion, a pyridinium ion, and the like), phosphonium ions (for example, a tetraalkylphosphonium ion such as a tetrabutylphosphonium ion, an alkyltriphenylphosphonium ion, a triethylphenylphosphonium ion, and the like), and alkali metal ions.

[Regarding Formula (7)]

In Formula (7), X² and X³ each independently represent O or NRx, where Rx represents a hydrogen atom or a substituent.

Examples of the substituent represented by Rx include a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, and a phosphino group, and a hydrocarbon group is more preferable and an alkyl group is still more preferable. The details of these groups are synonymous in ranges described in Formula (1).

X² and X³ are preferably O or NRx in which Rx is a substituent.

Specific examples of the compound A include compounds described in Examples described later, and compounds described in paragraphs “0081” to “0085” of JP2016-075739A.

The content of the compound A is 0.1 to 10 parts by mass with respect to 100 parts by mass of the green pigment. In a case where the content of the compound A is within the above-described range, excellent storage stability can be obtained. The lower limit of the content of the compound A is preferably 0.2 part by mass or more and more preferably 0.5 parts by mass or more. The upper limit thereof is preferably 5 parts by mass or less and more preferably 3 parts by mass or less. In addition, the content of the compound A in the total solid content of the coloring composition is preferably 0.01 to 5 mass %. The lower limit is preferably 0.1 mass % or more and more preferably 0.2 mass % or more. The upper limit is preferably 3 mass % or less, more preferably 2 mass % or less, and still more preferably 1 mass % or less. As the compound A, one kind may be used alone, or two or more kinds may be used in combination. In a case where two or more kinds of compounds A are used in combination, the total content of the two or more kinds of compounds A is within the above-described range.

“Resin”

The coloring composition according to the embodiment of the present invention contains a resin. The resin is blended in, for example, an application for dispersing particles such as a pigment in a coloring composition or an application as a binder. Mainly, a resin which is used for dispersing particles such as a pigment is also referred to as a dispersant.

However, such applications of the resin are merely exemplary, and the resin can also be used for other purposes in addition to such applications.

The weight-average molecular weight (Mw) of the resin is preferably 3000 to 2000000. The upper limit is preferably 1000000 or less and more preferably 500000 or less. The lower limit is preferably 4000 or more and more preferably 5000 or more.

(Graft Resin)

In the present invention, the resin is preferably a resin (hereinafter, also referred to as a graft resin) including a repeating unit having a graft chain. According to this aspect, dispersibility of the green pigment can be further improved, and the storage stability of the coloring composition can be further improved. Furthermore, the aggregation of pigments can be easily suppressed, and as a result, generation of residues after development can be suppressed, and developability can be further improved. The graft resin can be preferably used as a dispersant. Here, the graft chain means a polymer chain branched from the main chain of the repeating unit. The length of the graft chain is not particularly limited, and in a case where the graft chain gets longer, a steric repulsion effect is enhanced, and thus, the dispersibility of a pigment or the like can be increased. In the graft chain, the number of atoms excluding the hydrogen atoms is preferably 40 to 10000, the number of atoms excluding the hydrogen atoms is more preferably 50 to 2000, and the number of atoms excluding the hydrogen atoms is still more preferably 60 to 500.

The graft chain preferably includes at least one structure selected from a polyester chain, a polyether chain, a poly(meth)acryl chain, a polyurethane chain, a polyurea chain, or a polyamide chain, and more preferably includes at least one structure selected from a polyester chain, a polyether chain, or a poly(meth)acryl chain.

A terminal structure of the graft chain is not particularly limited. The terminal structure may be a hydrogen atom or a substituent. Examples of the substituent include an alkyl group, an aryl group, a heteroaryl group, an alkoxy group, an aryloxy group, a heteroaryloxy group, an alkylthioether group, an arylthioether group, a heteroarylthioether group, a hydroxy group, and an amino group. Among these, from the viewpoint of improvement of the dispersibility of the pigment or the like, a group having a steric repulsion effect is preferable, and an alkyl group or alkoxy group having 5 to 24 carbon atoms is more preferable. The alkyl group and the alkoxy group may be linear, branched, or cyclic, and are preferably linear or branched.

The weight-average molecular weight of the graft chain is preferably 500 to 10000. The upper limit is preferably 8000 or less and more preferably 6000 or less. The lower limit is preferably 1000 or more and more preferably 1500 or more. In a case where the weight-average molecular weight of the graft chain is 10000 or less, excellent developability can be obtained. In addition, in a case where the weight-average molecular weight of the graft chain is 500 or more, the dispersibility of the pigment can be improved, and the storage stability of the coloring composition can be improved. In the present specification, the weight-average molecular weight of the graft chain is a value calculated from the weight-average molecular weight of the raw material monomer used for the polymerization of the repeating unit having the graft chain. For example, the repeating unit having the graft chain can be formed by polymerizing a macromonomer. Here, the macromonomer means a polymer compound in which a polymerizable group is introduced at a polymer terminal. In addition, as the value of the weight-average molecular weight of the raw material monomer, a value in terms of polystyrene through measurement by a gel permeation chromatography (GPC) method is used.

Examples of the repeating unit having a graft chain include repeating units represented by Formulae (Gf1) to (Gf4).

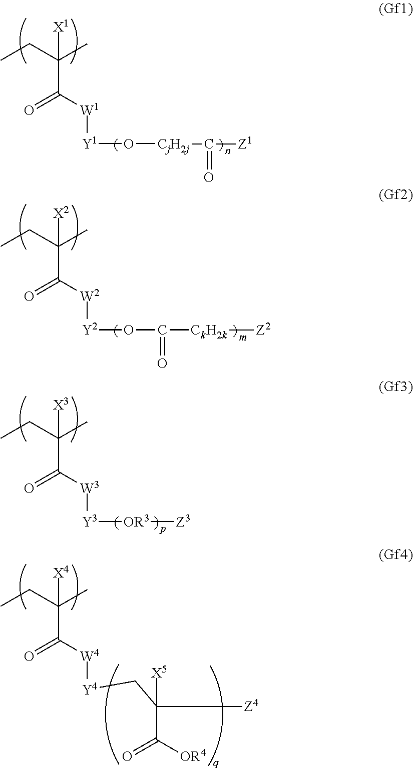

In Formulae (Gf1) to (Gf4), W¹, W², W³, and W⁴ each independently represent an oxygen atom or NH, X¹, X², X³, X⁴, and X⁵ each independently represent a hydrogen atom or a substituent, Y¹, Y², Y³, and Y⁴ each independently represent a divalent linking group, Z¹, Z², Z³, and Z⁴ each independently represent a hydrogen atom or a substituent, R³ represents an alkylene group, R⁴ represents a hydrogen atom or a substituent, n, m, p, and q each independently represent an integer of 1 to 500, and j and k each independently represent an integer of 2 to 8. In Formula (Gf3), in a case where p is 2 to 500, a plurality of R³'s may be the same or different from each other. In Formula (Gf4), in a case where q is 2 to 500, a plurality of X⁵'s and R⁴'s may be the same or different from each other.

W¹, W², W³, and W⁴ are preferably an oxygen atom. X¹, X², X³, X⁴, and X⁵ are preferably a hydrogen atom or an alkyl group having 1 to 12 carbon atoms, more preferably a hydrogen atom or a methyl group, and particularly preferably a methyl group. Y¹, Y², Y³, and Y⁴ each independently represent a divalent linking group, and the linking group is not particularly restricted in the structure. Examples thereof include an alkylene group (preferably, an alkylene group having 1 to 12 carbon atoms), an arylene group (preferably, an arylene group having 6 to 20 carbon atoms), —NH—, —SO—, —SO₂—, —CO—, —O—, —COO—, —OCO—, —S—, and a group formed by combination of two or more of these groups. Examples of the substituent represented by Z¹, Z², Z³, and Z⁴ include an alkyl group, an aryl group, a heteroaryl group, an alkoxy group, an aryloxy group, a heteroaryloxy group, an alkylthioether group, an arylthioether group, a heteroarylthioether group, a hydroxy group, and an amino group.

From the viewpoint of improving dispersibility, the substituent represented by Z¹, Z², Z³, and Z⁴ preferably has a steric repulsion effect, is more preferably an alkyl group having 5 to 24 carbon atoms or an alkoxy group having 5 to 24 carbon atoms, and still more preferably a branched alkyl group having 5 to 24 carbon atoms, a cyclic alkyl group having 5 to 24 carbon atoms, or an alkoxy group having 5 to 24 carbon atoms. An alkyl group included in the alkoxy group may be linear, branched, or cyclic.

In Formulae (Gf1) to (Gf4), n, m, p, and q each independently represent an integer of 1 to 500. In addition, in Formulae (Gf1) and (Gf2), j and k each independently represent an integer of 2 to 8. j and k in Formulae (Gf1) and (Gf2) are preferably an integer of 4 to 6 and most preferably 5 from the viewpoint of dispersion stability and developability.

In Formula (Gf3), R³ represents an alkylene group, and an alkylene group having 1 to 10 carbon atoms is preferable and an alkylene group having 2 or 3 carbon atoms is more preferable. In a case where p is 2 to 500, a plurality of R³'s may be the same or different from each other.

In Formula (Gf4), R⁴ represents a hydrogen atom or a substituent. Examples of the substituent include an alkyl group, an aryl group, and a heteroaryl group. R⁴ is preferably a hydrogen atom or an alkyl group. In Formula (Gf4), in a case where q is 2 to 500, a plurality of X⁵'s and R⁴'s may be the same or different from each other.

In all the repeating units of the graft resin, the graft resin preferably includes 1 mol % or more of the repeating unit having a graft chain, more preferably includes 2 mol % or more thereof, and still more preferably includes 3 mol % or more thereof. The upper limit may be 100 mol %, 90 mol % or less, 80 mol % or less, 70 mol % or less, or 60 mol % or less.

The graft resin may further include a repeating unit other than the repeating unit having a graft chain. Examples of other repeating units include a repeating unit having an acid group and a repeating unit having a polymerizable group. Examples of the acid group include a carboxy group, a sulfo group, and a phosphoric acid group. Examples of the polymerizable group include ethylenically unsaturated groups such as a vinyl group, a (meth)allyl group, and a (meth)acryloyl group.

In a case where the graft resin further includes the repeating unit having an acid group, alkali developability can be imparted and the developability can be further improved. In addition, in a case where the graft resin further includes the repeating unit having a polymerizable group, it is easy to obtain a film having excellent various physical properties such as heat resistance.

In a case where the graft resin includes the repeating unit having an acid group, the content of the repeating unit having an acid group is preferably 40 to 90 mol % with respect to all the repeating units of the graft resin. The lower limit is preferably 50 mol % or more and more preferably 60 mol % or more. The upper limit is preferably 80 mol % or less and more preferably 75 mol % or less.

In a case where the graft resin includes the repeating unit having a polymerizable group, the content of the repeating unit having a polymerizable group is preferably 10 to 50 mol % with respect to all the repeating units of the graft resin. The lower limit is preferably 15 mol % or more and more preferably 20 mol % or more. The upper limit is preferably 45 mol % or less and more preferably 40 mol % or less.

The weight-average molecular weight of the graft resin is preferably 3000 to 50000. The lower limit is preferably 5000 or more and more preferably 7000 or more. The upper limit is preferably 40000 or less and more preferably 30000 or less. In a case where the weight-average molecular weight of the graft resin is within the above-described range, it is easy to achieve both excellent developability and storage stability.

The acid value of the graft resin is preferably 20 to 150 mgKOH/g. The upper limit is preferably 130 mgKOH/g or less and more preferably 110 mgKOH/g or less. The lower limit is preferably 30 mgKOH/g or more and more preferably 40 mgKOH/g or more. In a case where the acid value of the graft resin is within the above-described range, it is easy to achieve both excellent developability and storage stability.

Specific examples of the graft resin include resins described in paragraphs “0025” to 0094” of JP2012-255128A and resins having the following structures.

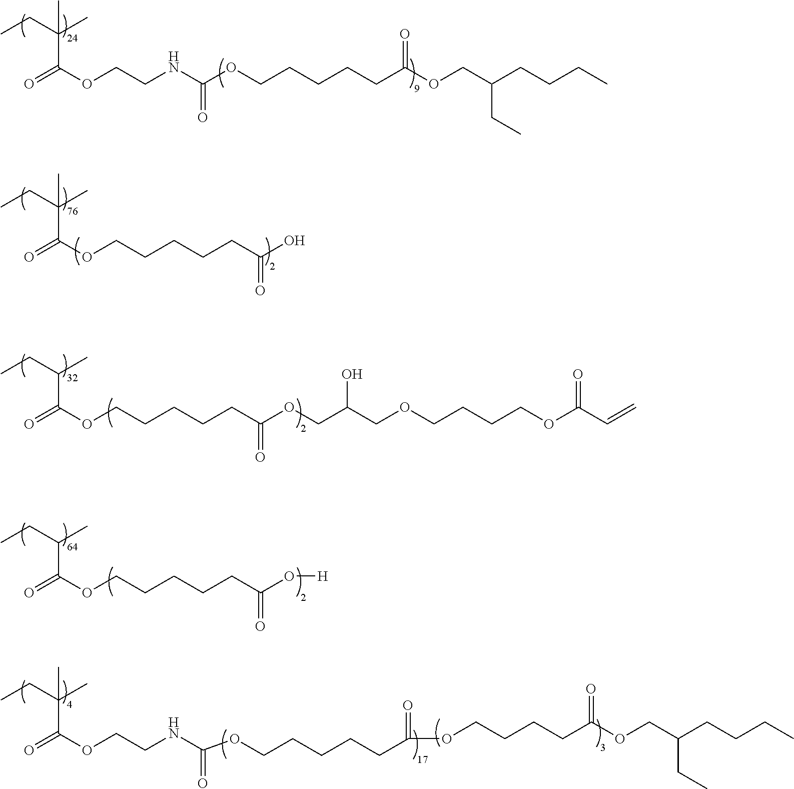

(Other Resins)

The coloring composition according to the embodiment of the present invention can include a resin (hereinafter, also referred to as other resins) other than the above-described graft resin.

The weight-average molecular weight (Mw) of the other resins is preferably 2000 to 2000000. The upper limit is preferably 1000000 or less and more preferably 500000 or less.

The lower limit is preferably 3000 or more, more preferably 4000 or more, and still more preferably 5000 or more.

Examples of the resin include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamideimide resin, a polyolefin resin, a cyclic olefin resin, a polyester resin, and a styrene resin. These resins may be used singly or as a mixture of two or more kinds thereof. In addition, resins described in paragraphs “0041” to “0060” of JP2017-206689A, and resins described in paragraphs “0022” to “0071” of JP2018-010856A can also be used.

The other resins are also preferably a resin having an acid group. According to this aspect, developability of the coloring composition can be improved, and pixels having excellent rectangularity can be easily formed by using a photolithography method. Examples of the acid group include a carboxy group, a phosphoric acid group, a sulfo group, and a phenolic hydroxy group, and a carboxy group is preferable. The resin having an acid group can also be used as, for example, an alkali-soluble resin and a dispersant.

The resin having an acid group as the other resins preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

It is also preferable that the resin having an acid group as the other resins includes a repeating unit derived from a compound represented by Formula (ED1) and/or a compound represented by Formula (ED2) (hereinafter, these compounds may be referred to as an “ether dimer”).

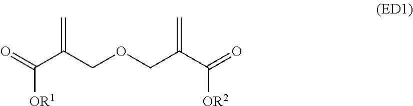

In Formula (ED1), R¹ and R² each independently represent a hydrogen atom or a hydrocarbon group having 1 to 25 carbon atoms, which may have a substituent.

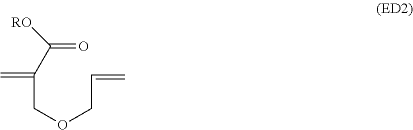

In Formula (ED2), R represents a hydrogen atom or an organic group having 1 to 30 carbon atoms. Specific examples of the compound represented by Formula (ED2) include compounds described in JP2010-168539A.

Specific examples of the ether dimer can be found in paragraph “0317” of JP2013-029760A, the contents of which are incorporated herein by reference.

The resin having an acid group as the other resins are also preferably a resin including a repeating unit having a polymerizable group. Examples of the polymerizable group include ethylenically unsaturated groups such as a vinyl group, a (meth)allyl group, and a (meth)acryloyl group.

It is also preferable that the resin having an acid group as the other resins are a resin including a repeating unit derived from a compound represented by Formula (X).

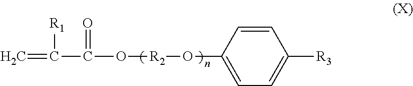

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring, n represents an integer of 1 to 15.

The acid value of the resin having an acid group as the other resins is preferably 30 to 500 mgKOH/g. The lower limit is more preferably 50 mgKOH/g or more and still more preferably 70 mgKOH/g or more. The upper limit is more preferably 400 mgKOH/g or less, still more preferably 200 mgKOH/g or less, particularly preferably 150 mgKOH/g or less, and most preferably 120 mgKOH/g or less. In addition, the weight-average molecular weight (Mw) thereof is preferably 5000 to 100000. In addition, the number-average molecular weight (Mn) thereof is preferably 1000 to 20000.

Specific examples of the resin having an acid group include resins having the following structures.

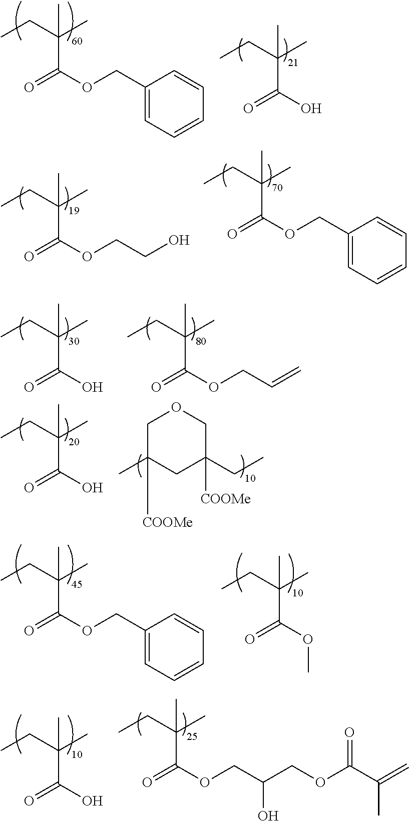

The other resins are also preferably a dispersant. Examples of the other resins as a dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total content of the acid group and the basic group is 100 mol %, and more preferably a resin substantially consisting of only an acid group. The acid group included in the acidic dispersant (acidic resin) is preferably a carboxy group. The acid value of the acidic dispersant (acidic resin) is preferably 10 to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. A basic group included in the basic dispersant is preferably an amino group.

The other resins used as a dispersant preferably include a repeating unit having an acid group. In a case where the other resins used as a dispersant include a repeating unit having an acid group, the generation of the development residue can be further suppressed in the formation of a pattern by a photolithography method.

It is also preferable that the other resins used as a dispersant are a polyimine-based dispersant including a nitrogen atom in at least one of the main chain or the side chain. As the polyimine-based dispersant, a resin having a main chain which has a partial structure having a functional group of pKa14 or less, and a side chain which has 40 to 10000 atoms, in which at least one of the main chain or the side chain has a basic nitrogen atom, is preferable.

The basic nitrogen atom is not particularly limited as long as it is a nitrogen atom exhibiting basicity. With regard to the polyimine-based dispersant, reference can be made to the description in paragraphs “0102” to “0166” of JP2012-255128A, the contents of which are incorporated herein by reference.

It is also preferable that the other resins used as a dispersant are a resin having a structure in which a plurality of polymer chains are bonded to a core portion. Examples of such a resin include dendrimers (including star polymers). In addition, specific examples of the dendrimer include polymer compounds C-1 to C-31 described in paragraphs “0196” to “0209” of JP2013-043962A.

It is also preferable that the other resins used as a dispersant are a resin including a repeating unit having an ethylenically unsaturated bonding group in the side chain. The content of the repeating unit having an ethylenically unsaturated bonding group in the side chain is preferably 10 mol % or more, more preferably 10 to 80 mol %, and still more preferably 20 to 70 mol % with respect to all the repeating units of the resin.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. In addition, pigment dispersants described in paragraphs “0041” to “0130” of JP2014-130338A can also be used, the contents of which are incorporated herein by reference. The resin described as a dispersant can be used for an application other than the dispersant. For example, the resin can also be used as a binder.

The content of the resin in the total solid content of the coloring composition is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less.

The content of the graft resin in the total solid content of the coloring composition is preferably 3 to 40 mass %. The lower limit is preferably 5 mass % or more and more preferably 10 mass % or more. The upper limit is preferably 30 mass % or less, more preferably 25 mass % or less, and still more preferably 20 mass % or less. In a case where the content of the graft resin is within the above-described range, more excellent storage stability can be easily obtained. In addition, the content of the graft resin is preferably 20 to 70 parts by mass with respect to 100 parts by mass of the green pigment. The lower limit is preferably 25 parts by mass or more and more preferably 30 parts by mass or more. The upper limit is preferably 60 parts by mass or less, more preferably 50 parts by mass or less, and still more preferably 45 parts by mass or less. In a case where the content of the graft resin is within the above-described range, more excellent storage stability can be easily obtained.

In addition, the content of the resin having an acid group in the total solid content of the coloring composition is preferably 5 to 50 mass %. The lower limit is preferably 10 mass % or more and more preferably 15 mass % or more. The upper limit is preferably 40 mass % or less, more preferably 35 mass % or less, and still more preferably 30 mass % or less. In addition, from the reason that excellent developability is easily obtained, the content of the resin having an acid group in the total amount of the resin is preferably 30 mass % or more, more preferably 50 mass % or more, still more preferably 70 mass % or more, and particularly preferably 80 mass % or more. The upper limit may be 100 mass %, 95 mass %, or 90 mass % or less. In a case where the graft resin has an acid group, such a graft resin also corresponds to the resin having an acid group.

“Pigment Derivative”

The coloring composition according to the embodiment of the present invention can contain a pigment derivative. According to this aspect, storage stability of the coloring composition can be further improved. Examples of the pigment derivative include a compound having a structure in which a portion of a pigment is substituted with an acid group, a basic group, a group having a salt structure, or a phthalimidomethyl group. As the pigment derivative, a compound represented by Formula (B1) is preferable.

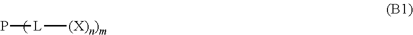

In Formula (B1), P represents a coloring agent structure, L represents a single bond or a linking group, X represents an acid group, a basic group, a group having a salt structure, or a phthalimidomethyl group, m represents an integer of 1 or more, n represents an integer of 1 or more, in a case where m represents 2 or more, a plurality of L's and a plurality of X's may be different from each other, and in a case where n represents 2 or more, a plurality of X's may be different from each other.

Examples of the coloring agent structure represented by P include a pyrrolopyrrole coloring agent structure, a diketopyrrolopyrrole coloring agent structure, a quinacridone coloring agent structure, an anthraquinone coloring agent structure, a dianthraquinone coloring agent structure, a benzoisoindole coloring agent structure, a thiazine indigo coloring agent structure, an azo coloring agent structure, a quinophthalone coloring agent structure, a phthalocyanine coloring agent structure, a naphthalocyanine coloring agent structure, a dioxazine coloring agent structure, a perylene coloring agent structure, a perinone coloring agent structure, a benzimidazolone coloring agent structure, a benzothiazole coloring agent structure, a benzimidazole coloring agent structure, and a benzoxazole coloring agent structure.

Examples of the linking group represented by L include a hydrocarbon group, a heterocyclic group, —NR—, —SO₂—, —S—, —O—, —CO—, or a group of a combination of these groups. R represents a hydrogen atom, an alkyl group, or an aryl group.

Examples of the acid group represented by X include a carboxy group, a sulfo group, a carboxylic acid amide group, a sulfonic acid amide group, and an imide acid group. As the carboxylic acid amide group, a group represented by —NHCOR^{X1} is preferable. As the sulfonic acid amide group, a group represented by —NHSO₂R^{X2} is preferable. As the imide acid group, a group represented by —SO₂NHSO₂R^{X3}, —CONHSO₂R^{X4}, —CONHCOR^{X5}, or —SO₂NHCOR^{X6} is preferable. R^{X1} to R^{X6} each independently represent a hydrocarbon group or a heterocyclic group. The hydrocarbon group and heterocyclic group represented by R^{X1} to R^{X6} may further have a substituent. As the substituent which may be further included, a halogen atom is preferable and a fluorine atom is more preferable. Examples of the basic group represented by X include an amino group. Examples of the salt structure represented by X include a salt of the acid group or the basic group described above.

Examples of the pigment derivative include compounds having the following structures. In addition, for example, compounds described in JP1981-118462A (JP-S56-118462A), JP1988-264674A (JP-S63-264674A), JP1989-217077A (JP-H01-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraphs “0086” to “0098” of WO2011/024896A, paragraphs “0063” to “0094” of WO2012/102399A, paragraph “0082” of WO2017/038252A, paragraph “0171” of JP2015-151530A, paragraphs “0162” to “0183” of JP2011-252065A, JP2003-081972A, JP5299151B, JP2015-172732A, JP2014-199308A, JP2014-085562A, JP2014-035351A, and JP2008-081565A can be used, the contents of which are incorporated herein by reference.

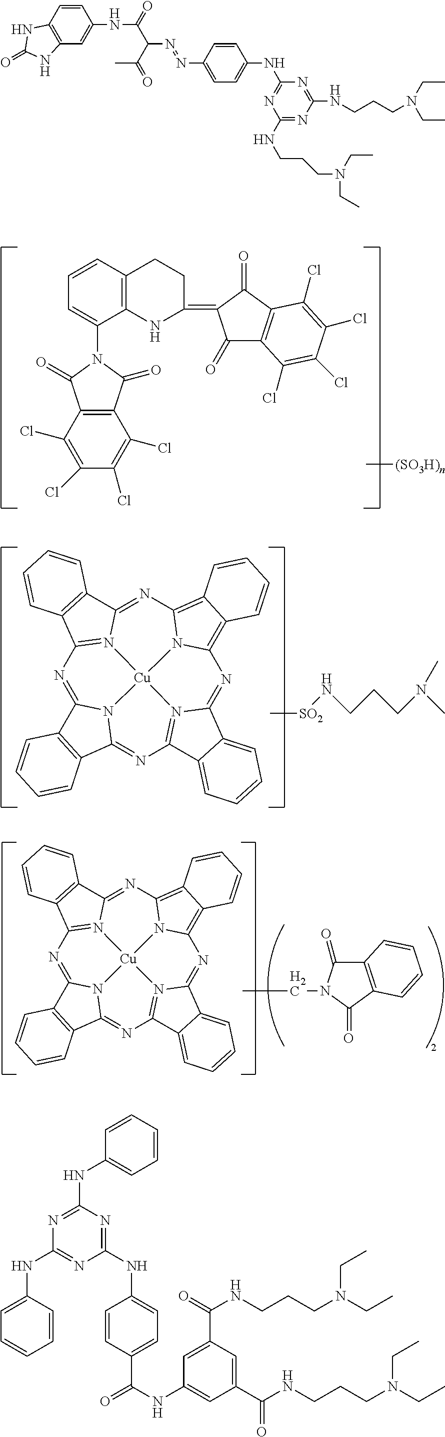

The content of the pigment derivative in the total solid content of the coloring composition is preferably 0.3 to 20 mass %. The lower limit is preferably 0.6 mass % or more and more preferably 0.9 mass % or more. The upper limit is preferably 15 mass % or less, more preferably 12.5 mass % or less, and still more preferably 10 mass % or less.

In addition, the content of the pigment derivative is preferably 1 to 30 parts by mass with respect to 100 parts by mass of the pigment. The lower limit is preferably 2 parts by mass or more and more preferably 3 parts by mass or more. The upper limit is preferably 25 parts by mass or less, more preferably 20 parts by mass or less, and still more preferably 15 parts by mass or less. As the pigment derivative, one kind may be used alone, or two or more kinds may be used in combination. In a case where two or more kinds of pigment derivatives are used in combination, it is preferable that the total content of the two or more kinds of pigment derivatives is within the above-described range.

“Polymerizable Compound”

It is preferable that the coloring composition according to the embodiment of the present invention contains a polymerizable compound. As the polymerizable compound, a known compound which is cross-linkable by a radical, an acid, or heat can be used. In the present invention, the polymerizable compound is preferably, for example, a compound having an ethylenically unsaturated bonding group. Examples of the ethylenically unsaturated bonding group include a vinyl group, a (meth)allyl group, and a (meth)acryloyl group. The polymerizable compound used in the present invention is preferably a radically polymerizable compound.

Any chemical forms of a monomer, a prepolymer, an oligomer, or the like may be used as the polymerizable compound, but a monomer is preferable. The molecular weight of the polymerizable compound is preferably 100 to 3000. The upper limit is more preferably 2000 or less and still more preferably 1500 or less. The lower limit is more preferably 150 or more and still more preferably 250 or more.

The polymerizable compound is preferably a compound including 3 or more ethylenically unsaturated bonding groups, more preferably a compound including 3 to 15 ethylenically unsaturated bonding groups, and still more preferably a compound including 3 to 6 ethylenically unsaturated bonding groups. In addition, the polymerizable compound is preferably a 3- to 15-functional (meth)acrylate compound and more preferably a 3- to 6-functional (meth)acrylate compound. Specific examples of the polymerizable compound include compounds described in paragraphs “0095” to “0108” of JP2009-288705A, paragraph “0227” of JP2013-029760A, paragraphs “0254” to “0257” of JP2008-292970A, paragraphs “0034” to “0038” of JP2013-253224A, paragraph “0477” of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which the (meth)acryloyl group of these compounds is bonded through an ethylene glycol and/or a propylene glycol residue (for example, SR454 and SR499 which are commercially available from Sartomer) is preferable. In addition, as the polymerizable compound, diglycerin ethylene oxide (EO)-modified (meth)acrylate (as a commercially available product, M-460 manufactured by TOAGOSEI CO., LTD.), pentaerythritol tetraacrylate (NK ESTER A-TMMT manufactured by Shin-Nakamura Chemical Co., Ltd.), 1,6-hexanediol diacrylate (KAYARAD HDDA manufactured by Nippon Kayaku Co., Ltd.), RP-1040 (manufactured by Nippon Kayaku Co., Ltd), ARONIX TO-2349 (manufactured by TOAGOSEI CO., LTD.), NK OLIGO UA-7200 (manufactured by Shin-Nakamura Chemical Co., Ltd.), 8UH-1006 and 8UH-1012 (manufactured by Taisei Fine Chemical Co., Ltd.), Light Acrylate POB-A0 (manufactured by KYOEISHA CHEMICAL Co., Ltd.), and the like can also be used.

In addition, as the polymerizable compound, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the polymerizable compound in an unexposed area is easily removed during development and the generation of the development residue can be suppressed. Examples of the acid group include a carboxy group, a sulfo group, and a phosphoric acid group, and a carboxy group is preferable. Examples of a commercially available product of the polymerizable compound having an acid group include ARONIX M-510, M-520, and ARONIX TO-2349 (manufactured by TOAGOSEI CO., LTD.). The acid value of the polymerizable compound having an acid group is preferably 0.1 to 40 mgKOH/g and more preferably 5 to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a polymerizable compound having an alkyleneoxy group can also be used. The polymerizable compound having an alkyleneoxy group is preferably a polymerizable compound having an ethyleneoxy group and/or a propyleneoxy group, more preferably a polymerizable compound having an ethyleneoxy group, and still more preferably a 3- to 6-functional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having four ethyleneoxy groups, and KAYARAD TPA-330, which is a trifunctional (meth)acrylate having three isobutyleneoxy groups.

As the polymerizable compound, a polymerizable compound having a fluorene skeleton can also be used. Examples of a commercially available product of the polymerizable compound having a fluorene skeleton include OGSOL EA-0200, EA-0300 (manufactured by Osaka Gas Chemicals Co., Ltd., (meth)acrylate monomer having a fluorene skeleton).

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

As the polymerizable compound, urethane acrylates described in JP1973-041708B (JP-S48-041708B), JP1976-037193A (JP-S51-037193A), JP1990-032293B (JP-H02-032293B), and JP1990-016765B (JP-H02-016765B); urethane compounds having an ethylene oxide skeleton described in JP1983-049860B (JP-S58-049860B), JP1981-017654B (JP-S56-017654B), JP1987-039417B (JP-S62-039417B), and JP1987-039418B (JP-S62-039418B); or polymerizable compounds having an amino structure or a sulfide structure in the molecule, described in JP1988-277653A (JP-S63-277653A), JP1988-260909A (JP-S63-260909A), and JP1989-105238A (JP-H01-105238A) can also be preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

The content of the polymerizable compound in the total solid content of the coloring composition is preferably 0.1 to 50 mass %. The lower limit is more preferably 0.5 mass % or more and still more preferably 1 mass % or more. The upper limit is more preferably 45 mass % or less and still more preferably 40 mass % or less. The polymerizable compound may be used singly or in combination of two or more kinds thereof. In a case where two or more kinds of polymerizable compounds are used in combination, it is preferable that the total of the two or more kinds of polymerizable compounds is within the above-described range.

In addition, from the viewpoint of curability, developability, and film-forming property, the total content of the polymerizable compound and resin in the total solid content of the coloring composition is preferably 10 to 65 mass %. The lower limit is preferably 15 mass % or more, more preferably 20 mass % or more, and still more preferably 30 mass % or more. The upper limit is preferably 60 mass % or less, more preferably 50 mass % or less, and still more preferably 40 mass % or less. In addition, the coloring composition according to the embodiment of the present invention preferably contains 30 to 300 parts by mass of the resin with respect to 100 parts by mass of the polymerizable compound. The lower limit is preferably 50 parts by mass or more and more preferably 80 parts by mass or more. The upper limit is preferably 250 parts by mass or less and more preferably 200 parts by mass or less.

“Photopolymerization Initiator”

It is preferable that the coloring composition according to the embodiment of the present invention includes a photopolymerization initiator. In particular, in a case where the coloring composition according to the embodiment of the present invention includes the polymerizable compound, it is preferable that the coloring composition according to the embodiment of the present invention further includes a photopolymerization initiator. The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an a-hydroxyketone compound, an a-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an a-hydroxyketone compound, an a-aminoketone compound, and an acylphosphine compound is more preferable, and an oxime compound is still more preferable. In addition, examples of the photopolymerization initiator include compounds described in paragraphs 0065 to 0111 of JP2014-130173A, and JP6301489B, the contents of which are incorporated herein by reference.

Examples of a commercially available product of the a-hydroxyketone compound include IRGACURE-184, DAROCUR-1173, IRGACURE-500, IRGACURE-2959, and IRGACURE-127 (all of which are manufactured by BASF). Examples of a commercially available product of the a-aminoketone compound include IRGACURE-907, IRGACURE-369, IRGACURE-379, and IRGACURE-379EG (all of which are manufactured by BASF). Examples of a commercially available product of the acylphosphine compound include IRGACURE-819, and DAROCUR-TPO (both of which are manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2000-080068A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraphs “0025” to “0038” of WO2017/164127A, and the compounds described in WO2013/167515A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxy imino-1-phenylpropan-1-one, 2-benzoyloxyimino-1-phenylpropan-1-one, 3-(4-toluene sulfonyloxy)iminobutan-2-one, and 2-ethoxycarbonyloxyimino-1-phenylpropan-1-one. Examples of a commercially available product thereof include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no coloring property or a compound having high transparency and being resistant to discoloration. Examples of a commercially available product thereof include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include compounds described in JP2014-137466A.

In addition, as the photopolymerization initiator, an oxime compound having a skeleton in which at least one benzene ring of a carbazole ring is a naphthalene ring can also be used.

Specific examples of such an oxime compound include the compounds described in WO2013/083505A.

In the present invention, an oxime compound having a fluorine atom can also be used as the photopolymerization initiator. Specific examples of the oxime compound having a fluorine atom include compounds described in JP2010-262028A, Compounds 24 and 36 to 40 described in JP2014-500852A, and Compound (C-3) described in JP2013-164471A.

In the present invention, an oxime compound having a nitro group can be used as the photopolymerization initiator. It is preferable that the oxime compound having a nitro group is a dimer. Specific examples of the oxime compound having a nitro group include a compound described in paragraphs “0031” to “0047” of JP2013-114249A and paragraphs “0008” to “0012” and “0070” to “0079” of JP2014-137466A, a compound described in paragraphs “0007” to 0025” of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

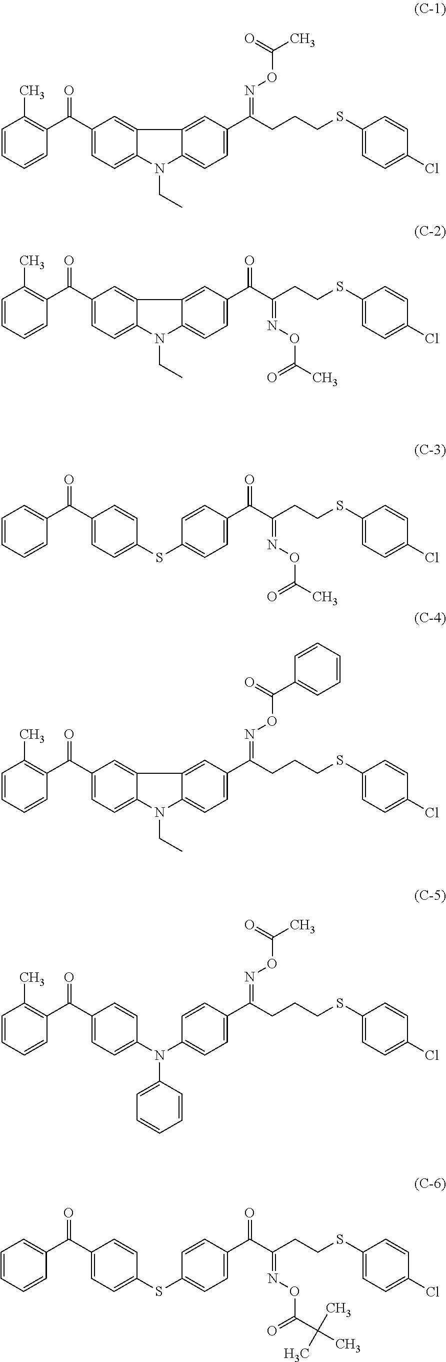 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Cl)cc1)C(=O)c1ccc(Sc2ccc(C(=O)c3ccccc3)cc2)cc1]

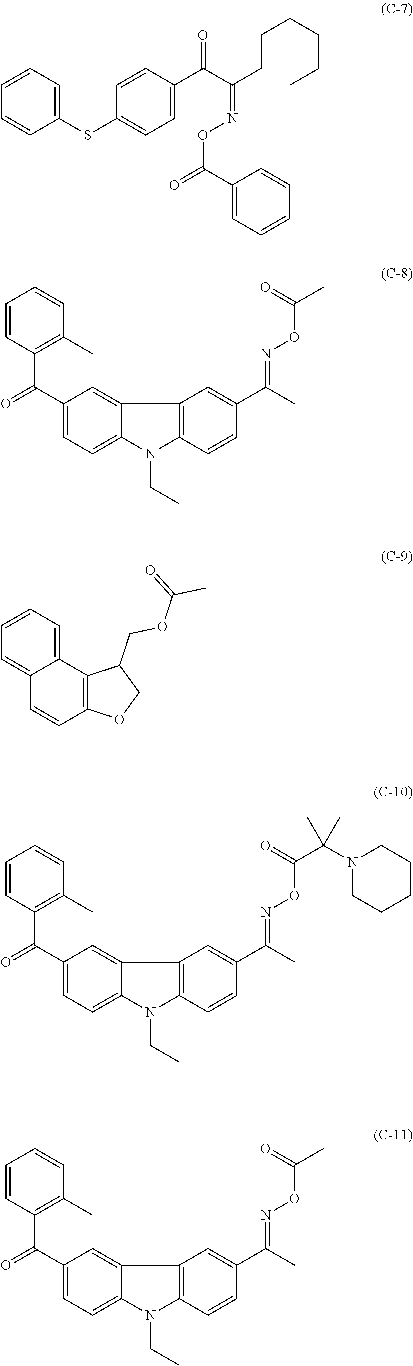 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)OCC1COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2cc(/C(C)=N/OC(C)=O)ccc21]

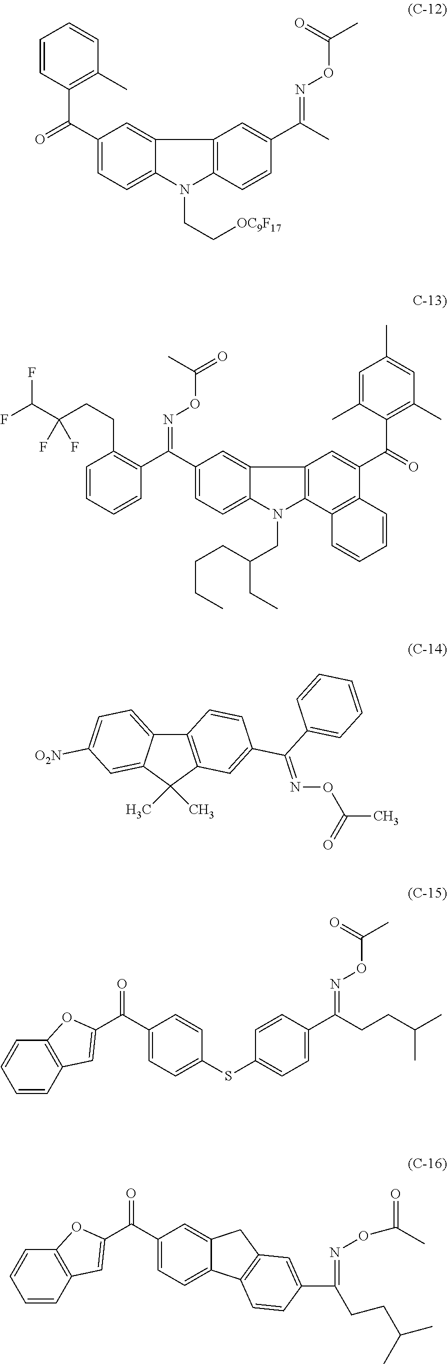

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a well-known method. For example, it is preferable that the molar absorption coefficient can be measured using a spectrophotometer (Cary-5 spectrophotometer, manufactured by Varian Medical Systems, Inc.) and ethyl acetate as a solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the coloring composition can be improved. Specific examples of the bifunctional or tri- or higher functional photoradical polymerization initiator include dimers of the oxime compounds described in JP2010-527339A, JP2011-524436A, WO2015/004565A, paragraphs “0407” to “0412” of JP2016-532675A, and paragraphs “0039” to “0055” of WO2017/033680A; the compound (E) and compound (G) described in JP2013-522445A; Cmpd 1 to 7 described in WO2016/034963A; the oxime ester photoinitiators described in paragraph “0007” of JP2017-523465A; the photoinitiators described in paragraphs “0020” to “0033” of JP2017-167399A; and the photopolymerization initiator (A) described in paragraphs “0017” to “0026” of JP2017-151342A.

In a case where the coloring composition according to the embodiment of the present invention contains a photopolymerization initiator, the content of the photopolymerization initiator in the total solid content of the coloring composition according to the embodiment of the present invention is preferably 0.1 to 30 mass %. The lower limit is preferably 0.5 mass % or more and more preferably 1 mass % or more. The upper limit is preferably 20 mass % or less and more preferably 15 mass % or less. In the coloring composition according to the embodiment of the present invention, the photopolymerization initiator may be used singly or in combination of two or more kinds thereof. In a case where two or more kinds thereof are used, the total content thereof is preferably within the above-described range.

“Compound having Cyclic Ether Group”

The coloring composition according to the embodiment of the present invention can contain a compound having a cyclic ether group. Examples of the cyclic ether group include an epoxy group and an oxetanyl group. The compound having a cyclic ether group is preferably a compound having an epoxy group. Examples of the compound having an epoxy group include a compound having one or more epoxy groups in one molecule, and a compound having two or more epoxy groups in one molecule is preferable. It is preferable to have 1 to 100 epoxy groups in one molecule. The upper limit of the number of epoxy groups may be, for example, 10 or less or 5 or less. The lower limit of the number of epoxy groups is preferably 2 or more. As the compound having an epoxy group, compounds described in paragraphs “0034” to “0036” of JP2013-011869A, paragraphs “0147” to “0156” of JP2014-043556A, and paragraphs “0085” to “0092” of JP2014-089408A, and compounds described in JP2017-179172A can also be used. The contents thereof are incorporated herein by reference.

The compound having an epoxy group may be either a low-molecular-weight compound (for example, having a molecular weight of less than 2000, and further, a molecular weight of less than 1000) or a high-molecular-weight compound (macromolecule) (for example, having a molecular weight of 1000 or more, and in a case of a polymer, having a weight-average molecular weight of 1000 or more). The weight-average molecular weight of the compound having an epoxy group is preferably 200 to 100000 and more preferably 500 to 50000. The upper limit of the weight-average molecular weight is preferably 10000 or less, more preferably 5000 or less, and still more preferably 3000 or less.

As the compound having an epoxy group, an epoxy resin can be preferably used. Examples of the epoxy resin include an epoxy resin which is a glycidyl etherified product of a phenol compound, an epoxy resin which is a glycidyl etherified product of various novolak resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. The epoxy equivalent of the epoxy resin is preferably 310 to 3300 g/eq, more preferably 310 to 1700 g/eq, and still more preferably 310 to 1000 g/eq.

Examples of a commercially available product of the compound having a cyclic ether group include EHPE 3150 (manufactured by Daicel Corporation), EPICLON N-695 (manufactured by DIC Corporation), and MARPROOF G-0150M, G-0105SA, G-0130SP, G-0250SP, G-1005S, G-1005SA, G-1010S, G-2050M, G-01100, and G-01758 (all of which are manufactured by NOF Corporation., an epoxy group-containing polymer).

In a case where the coloring composition according to the embodiment of the present invention contains a compound having a cyclic ether group, the content of the compound having a cyclic ether group in the total solid content of the coloring composition is preferably 0.1 to 20 mass %. The lower limit is, for example, preferably 0.5 mass % or more and more preferably 1 mass % or more. The upper limit is, for example, preferably 15 mass % or less and still more preferably 10 mass % or less. The compound having a cyclic ether group may be used singly or in combination of two or more kinds thereof. In a case of using two or more kinds thereof, the total content thereof is preferably within the above-described range.

“Silane Coupling Agent”

The coloring composition according to the embodiment of the present invention can contain a silane coupling agent. According to this aspect, adhesiveness of a film to be obtained with a support can be further improved. In the present invention, the silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraphs “0018” to “0036” of JP2009-288703A and the compounds described in paragraphs “0056” to “0066” of JP2009-242604A, the contents of which are incorporated herein by reference.

The content of the silane coupling agent in the total solid content of the coloring composition is preferably 0.1 to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total content thereof is preferably within the above-described range.

“Organic Solvent”

The coloring composition according to the embodiment of the present invention contains an organic solvent. Basically, the organic solvent is not particularly limited as long as it satisfies the solubility of the respective components and the application properties of the coloring composition. Examples of the organic solvent include an ester solvent, a ketone solvent, an alcohol solvent, an amide solvent, an ether solvent, and a hydrocarbon solvent. With regard to details thereof, reference can be made to the description in paragraph “0223” of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include isomers (compounds having the same number of atoms and different structures). In addition, only one kind of isomers may be included, or a plurality of isomers may be included.

In the present invention, the organic solvent preferably has the content of peroxides of 0.8 mmol/L or less, and more preferably, the organic solvent does not substantially include peroxides.

The content of the organic solvent in the coloring composition is preferably 10 to 95 mass %, more preferably 20 to 90 mass %, and still more preferably 30 to 90 mass %.

In addition, from the viewpoint of environmental regulation, it is preferable that the coloring composition according to the embodiment of the present invention does not substantially contain environmentally regulated substances. In the present invention, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as environmentally regulated substances in accordance with Registration Evaluation Authorization and Restriction of Chemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the coloring composition according to the embodiment of the present invention, and may be incorporated into the coloring composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, coloring composition produced by mixing these compounds, or the like.

“Polymerization Inhibitor”

The coloring composition according to the embodiment of the present invention can contain a polymerization inhibitor. Examples of the polymerization inhibitor include hydroquinone, p-methoxyphenol, di-tert-butyl-p-cresol, pyrogallol, tert-butylcatechol, benzoquinone, 4,4′-thiobis(3-methyl-6-tert-butylphenol), 2,2′-methylenebis(4-methyl-6-t-butylphenol), and an N-nitrosophenylhydroxyamine salt (an ammonium salt, a cerous salt, or the like). Among these, p-methoxyphenol is preferable. The content of the polymerization inhibitor in the total solid content of the coloring composition is preferably 0.0001 to 5 mass %.

“Surfactant”

The coloring composition according to the embodiment of the present invention can contain a surfactant. As the surfactant, various surfactants such as a fluorine-based surfactant, a nonionic surfactant, a cationic surfactant, an anionic surfactant, or a silicon-based surfactant can be used. Examples of the surfactant include surfactants described in paragraphs “0238” to “0245” of WO2015/166779A, the contents of which are incorporated herein by reference.

In the present invention, it is preferable that the surfactant is a fluorine-based surfactant. By containing a fluorine-based surfactant in the coloring composition, liquid characteristics (particularly, fluidity) are further improved, and liquid saving properties can be further improved. In addition, it is possible to form a film with a small thickness unevenness.

The fluorine content in the fluorine-based surfactant is preferably 3 to 40 mass %, more preferably 5 to 30 mass %, and particularly preferably 7 to 25 mass %. The fluorine-based surfactant in which the fluorine content is within the above-described range is effective in terms of the evenness of the thickness of the coating film or liquid saving properties and the solubility of the surfactant in the coloring composition is also good.

Examples of the fluorine-based surfactant include surfactants described in paragraphs “0060” to “0064” of JP2014-041318A (paragraphs “0060” to “0064” of the corresponding WO2014/017669A) and the like, and surfactants described in paragraphs “0117” to “0132” of JP2011-132503A, the contents of which are incorporated herein by reference. Examples of a commercially available product of the fluorine-based surfactant include: MEGAFACE F171, F172, F173, F176, F177, F141, F142, F143, F144, R³⁰, F437, F475, F479, F482, F554, F780, EXP, MFS-330 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by Asahi Glass Co., Ltd.); and POLYFOX PF636, PF656, PF6320, PF6520, and PF7002 (all of which are manufactured by OMNOVA Solutions Inc.).

In addition, as the fluorine-based surfactant, an acrylic compound which has a molecular structure having a functional group containing a fluorine atom and in which, by applying heat to the molecular structure, the functional group containing a fluorine atom is broken to volatilize a fluorine atom can also be suitably used. Examples of such a fluorine-based surfactant include MEGAFACE DS series (manufactured by DIC Corporation, The Chemical Daily, Feb. 22, 2016, Nikkei Business Daily, Feb. 23, 2016), for example, MEGAFACE DS-21.

In addition, as the fluorine-based surfactant, a polymer of a fluorine atom-containing vinyl ether compound having a fluorinated alkyl group or a fluorinated alkylene ether group, and a hydrophilic vinyl ether compound can be preferably used. With regard to such a fluorine-based surfactant, reference can be made to the description in JP2016-216602A, the contents of which are incorporated herein by reference.

As the fluorine-based surfactant, a block polymer can also be used. Examples thereof include compounds described in JP2011-089090A. As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) can also be preferably used. In addition, fluorine-containing surfactants described in paragraphs “0016” to “0037” of JP2010-032698A, or the following compounds are also exemplified as the fluorine-based surfactant used in the present invention.

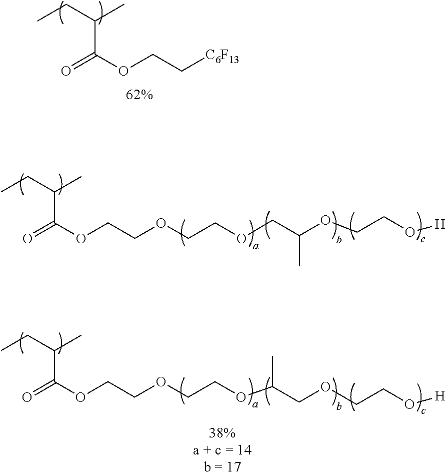

The weight-average molecular weight of the compound is preferably 3000 to 50000 and, for example, 14000. In the compound, “%” representing the proportion of a repeating unit is mol %.

In addition, as the fluorine-based surfactant, a fluorine-containing polymer including a repeating unit having an ethylenically unsaturated bonding group in the side chain can be used. Specific examples thereof include compounds described in paragraphs “0050” to “0090” and paragraphs “0289” to “0295” of JP2010-164965A, and for example, MEGAFACE RS-101, RS-102, RS-718K, and RS-72-K manufactured by DIC Corporation. In addition, as the fluorine-based surfactant, compounds described in paragraphs “0015” to “0158” of JP2015-117327A can also be used.

Examples of the nonionic surfactant include glycerol, trimethylolpropane, trimethylolethane, an ethoxylate and a propoxylate thereof (for example, glycerol propoxylate or glycerol ethoxylate), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, sorbitan fatty acid esters, PLURONIC L10, L31, L61, L62, 10R5, 17R2, and 25R2 (manufactured by BASF), TETRONIC 304, 701, 704, 901, 904, and 150R1 (manufactured by BASF), SOLSPERSE 20000 (manufactured by Lubrizol Corporation), NCW-101, NCW-1001, and NCW-1002 (all of which are manufactured by Wako Pure Chemical Industries, Ltd.), PIONIN D-6112, D-6112-W, and D-6315 (all of which are manufactured by Takemoto Oil&Fat Co., Ltd.), and OLFINE E1010 and SURFYNOL 104, 400, and 440 (all of which are manufactured by Nissin Chemical Co., Ltd.).

Examples of the silicon-based surfactant include TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.), TSF-4440, TSF-4300, TSF-4445, TSF-4460, and TSF-4452 (all of which are manufactured by Momentive Performance Materials Co., Ltd.), KP-341, KF-6001, and KF-6002 (all of which are manufactured by Shin-Etsu Chemical Co., Ltd.), and BYK307, BYK323, and BYK330 (all of which are manufactured by BYK Chemie).

The content of the surfactant in the total solid content of the coloring composition is preferably 0.001 mass % to 5.0 mass % and more preferably 0.005 to 3.0 mass %. The surfactant may be used singly or in combination of two or more kinds thereof. In a case of using two or more kinds thereof, the total content thereof is preferably within the above-described range.

“Ultraviolet Absorber”

The coloring composition according to the embodiment of the present invention can contain an ultraviolet absorber. As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, and the like can be used. Examples of details thereof include compounds described in paragraphs “0052” to “0072” of JP2012-208374A, paragraphs “0317” to “0334” of JP2013-068814A, and paragraphs “0061” to “0080” of JP2016-162946A, the contents of which are incorporated herein by reference. Specific examples of the ultraviolet absorber include compounds having the following structures. Examples of a commercially available product of the ultraviolet absorber include UV-503 (manufactured by Daito Chemical Co., Ltd.). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs “0049” to “0059” of JP6268967B can also be used.

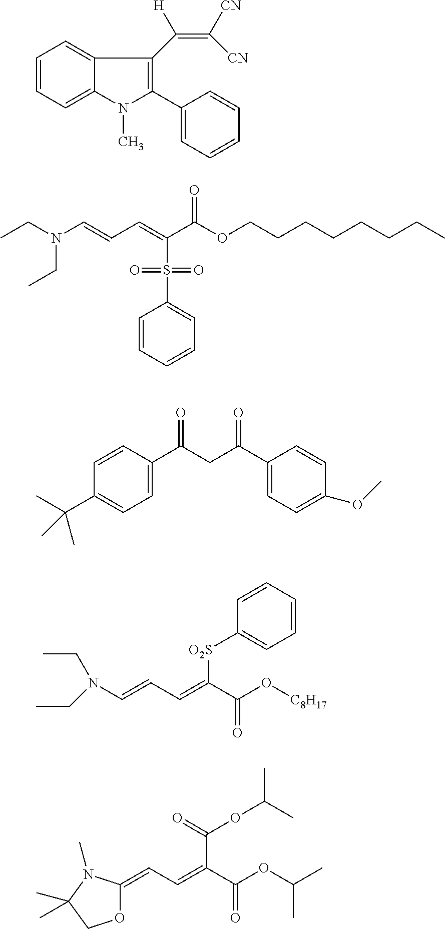

The content of the ultraviolet absorber in the total solid content of the coloring composition is preferably 0.01 to 10 mass % and more preferably 0.01 to 5 mass %. In the present invention, the ultraviolet absorber may be used singly or in combination of two or more kinds thereof. In a case where two or more kinds thereof are used, the total content thereof is preferably within the above-described range.

“Antioxidant”

The coloring composition according to the embodiment of the present invention can contain an antioxidant. Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitability used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraphs “0023” to “0048” of JP6268967B can also be used.

The content of the antioxidant in the total solid content of the coloring composition is preferably 0.01 to 20 mass % and more preferably 0.3 to 15 mass %. In the present invention, the antioxidant may be used singly or in combination of two or more kinds thereof. In a case where two or more kinds thereof are used, the total content thereof is preferably within the above-described range.

“Other Components”

Optionally, the coloring composition according to the embodiment of the present invention may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraphs “0183” and later of JP2012-003225A (corresponding to paragraph “0237” of US2013/0034812A) and paragraphs “0101” to “0104” and “0107” to “0109” of JP2008-250074A, the content of which is incorporated herein by reference. In addition, optionally, the coloring composition according to the embodiment of the present invention may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include the compounds described in WO2014/021023A, WO2017/030005A, and JP2017-008219A. Examples of a commercially available product of the potential antioxidant include ADEKA ARKLS GPA-5001 (manufactured by ADEKA Corporation). In addition, as described in JP2018-155881A, C. I. Pigment Yellow 129 may be added for the purpose of improving weather fastness.

In order to adjust the refractive index of the film to be obtained, the coloring composition according to the embodiment of the present invention may contain a metal oxide. Examples of the metal oxide include TiO₂, ZrO₂, Al₂O₃, and SiO₂. The primary particle diameter of the metal oxide is preferably 1 to 100 nm, more preferably 3 to 70 nm, and most preferably 5 to 50 nm. The metal oxide may have a core-shell structure. In addition, in this case, the core portion may be hollow.

In addition, the coloring composition according to the embodiment of the present invention may include a light-resistance improver. Examples of the light-resistance improver include the compounds described in paragraphs “0036” and “0037” of JP2017-198787A, the compounds described in paragraphs “0029” to “0034” of JP2017-146350A, the compounds described in paragraphs “0036” and “0037”, and “0049” to “0052” of JP2017-129774A, the compounds described in paragraphs “0031” to “0034”, “0058”, and “0059” of JP2017-129674A, the compounds described in paragraphs “0036” and “0037”, and “0051” to “0054” of JP2017-122803A, the compounds described in paragraphs “0025” to “0039” of WO2017/164127A, the compounds described in paragraphs “0034” to “0047” of JP2017-186546A, the compounds described in paragraphs “0019” to “0041” of JP2015-025116A, the compounds described in paragraphs “0101” to “0125” of JP2012-145604A, the compounds described in paragraphs “0018” to “0021” of JP2012-103475A, the compounds described in paragraphs “0015” to “0018” of JP2011-257591A, the compounds described in paragraphs “0017” to “0021” of JP2011-191483A, the compounds described in paragraphs “0108” to “0116” of JP2011-145668A, and the compounds described in paragraphs “0103” to “0153” of JP2011-253174A.

In the coloring composition according to the embodiment of the present invention, the content of liberating metal which is not bonded to or coordinated with a pigment or the like is preferably 100 ppm or less, more preferably 50 ppm or less, and still more preferably 10 ppm or less, it is particularly preferable to not contain the liberating metal substantially. According to this aspect, effects such as stabilization of pigment dispersibility (restraint of aggregation), improvement of spectral characteristics due to improvement of dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can be obtained.

Examples of the types of the above-described liberating metal include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the coloring composition according to the embodiment of the present invention, the content of liberating halogen which is not bonded to or coordinated with a pigment or the like is preferably 100 ppm or less, more preferably 50 ppm or less, and still more preferably 10 ppm or less, it is particularly preferable to not contain the liberating halogen substantially. Examples of halogen include F, Cl, Br, I, and anions thereof. Examples of a method for reducing liberating metals and halogens in the coloring composition include washing with ion exchange water, filtration, ultrafiltration, and purification with an ion exchange resin.

It is also preferable that the coloring composition according to the embodiment of the present invention does not substantially include terephthalic acid ester.

The moisture content in the coloring composition according to the embodiment of the present invention is usually 3 mass % or less, preferably 0.01 to 1.5 mass % and more preferably in a range of 0.1 to 1.0 mass %. The moisture content can be measured by a Karl Fischer method.

The coloring composition according to the embodiment of the present invention can be used after viscosity is adjusted for the purposes of adjusting the state of a film surface (flatness or the like), adjusting a film thickness, or the like. The value of the viscosity can be appropriately selected as desired, and is, for example, preferably 0.3 mPa×s to 50 mPa×s, and more preferably 0.5 mPa×s to 20 mPa×s at 23° C. As for a method for measuring the viscosity, the viscosity can be measured, for example, with a temperature being adjusted to 23° C., using a viscometer RE85L (rotor: 1°34′×R24, measurement range of 0.6 to 1,200 mPa×s) manufactured by Toki Sangyo Co., Ltd.

In a case where the coloring composition according to the embodiment of the present invention is used as a color filter in applications for a liquid crystal display device, the voltage holding ratio of a liquid crystal display element comprising a color filter is preferably 70% or more, and more preferably 90% or more. A known method for obtaining a high voltage holding ratio can be appropriately incorporated, and examples of typical methods include use of high-purity materials (for example, reduction in ionic impurities) and control of the amount of acidic functional groups in a composition. The voltage holding ratio can be measured by, for example, the methods described in paragraph 0243 of JP2011-008004A and paragraphs 0123 to 0129 of JP2012-224847A.

<Storage Container>

A storage container of the coloring composition according to the embodiment of the present invention is not particularly limited, and a known storage container can be used. In addition, as the storage container, in order to suppress infiltration of impurities into the raw materials or the coloring composition, a multilayer bottle in which a container inner wall having a six-layer structure is formed of six kinds of resins or a bottle in which a container inner wall having a seven-layer structure is formed of six kinds of resins is preferably used. Examples of such a container include a container described in JP2015-123351A. In addition, for the purpose of preventing metal elution from the container inner wall, improving storage stability of the coloring composition, and suppressing the alteration of components, it is also preferable that the inner wall of the storage container of the coloring composition is formed of glass, stainless steel, or the like.

Storage conditions of the coloring composition according to the embodiment of the present invention are not particularly limited, and a known method in the related art can be used. In addition, a method described in JP2016-180058A can be used.

<Method of Preparing Coloring Composition>

The coloring composition according to the embodiment of the present invention can be prepared by mixing the above-described components with each other. During the preparation of the coloring composition, all the components may be dissolved and/or dispersed in a solvent at the same time to prepare the coloring composition. Optionally, two or more solutions or dispersion liquids in which the respective components are appropriately blended may be prepared, and the solutions or dispersion liquids may be mixed with each other during use (during application) to prepare the coloring composition.

In addition, in the preparation of the coloring composition, a process of dispersing the pigment is preferably included. In the process of dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. In addition, it is preferable that rough particles are removed by filtering, centrifugal separation, and the like after pulverization treatment. In addition, as the process and the disperser for dispersing the pigment, the process and the disperser described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph “0022” of JP2015-157893A can be suitably used. In addition, in the process for dispersing the pigment, a miniaturization treatment of particles in a salt milling step may be performed. A material, a device, process conditions, and the like used in the salt milling step can be found in, for example, JP2015-194521A and JP2012-046629A.

Examples of the preferred aspect of the method of preparing the coloring composition include the following aspect 1 and aspect 2, and from the reason that the storage stability of the coloring composition can be more easily improved, the following aspect 1 is preferable.

Aspect 1: aspect in which the colorant including the green pigment, the compound A, the resin, and the solvent are mixed and dispersed to prepare a dispersion liquid, and the dispersion liquid is mixed with other components such as a resin as necessary to prepare a coloring composition.

Aspect 2: aspect in which the colorant including the green pigment, the resin, and the solvent are mixed and dispersed to prepare a dispersion liquid, and the dispersion liquid is mixed with the compound A and other components such as a resin as necessary to prepare a coloring composition.

During the preparation of the coloring composition, it is preferable that the coloring composition is filtered through a filter, for example, in order to remove foreign matter or to reduce defects. As the filter, any filter which is used in the related art for filtering or the like can be used without any particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including high-density polypropylene) or nylon is preferable.

The pore size of the filter is preferably 0.01 to 7.0 μm, more preferably 0.01 to 3.0 μm, and still more preferably 0.05 to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha, Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include polypropylene fiber, nylon fiber, and glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case where a filter is used, a combination of different filters (for example, a first filter and a second filter) may be used. In this case, the filtering using each of the filters may be performed once, or twice or more. In addition, a combination of filters having different pore sizes in the above-described range may be used. In addition, the filtering using the first filter may be performed only on the dispersion liquid, and the filtering using the second filter may be performed on a mixture of the dispersion liquid and other components.

<Film>

The film according to the embodiment of the present invention is a film obtained from the above-described coloring composition according to the embodiment of the present invention. The film according to the embodiment of the present invention can be used for a color filter or the like. Specifically, the film according to the embodiment of the present invention can be preferably used as a colored layer (pixel) of a color filter, and more specifically, the film according to the embodiment of the present invention can be preferably used as a green-colored layer (green pixel) or cyan-colored layer (cyan pixel) of a color filter, and more preferably used as a green-colored layer (green pixel) of a color filter. The thickness of the film according to the embodiment of the present invention can be appropriately adjusted according to the purpose. For example, the thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

<Color Filter>

Next, the color filter according to the embodiment of the present invention will be described. The color filter according to the embodiment of the present invention has the film according to the embodiment of the present invention. More preferably, the color filter according to the embodiment of the present invention has the film according to the embodiment of the present invention as a pixel of the color filter. The color filter according to the embodiment of the present invention can be used for a solid-state imaging element such as a charge coupled device (CCD) and a complementary metal-oxide semiconductor (CMOS), an image display device, or the like.

The color filter according to the embodiment of the present invention may further have a pixel (hereinafter, also referred to as other pixels) different from the film (pixel) according to the embodiment of the present invention. Examples of the other pixels include red pixels, blue pixels, yellow pixels, magenta pixels, transparent pixels, black pixels, and pixels of near infrared transmitting filter. For example, in a case where the film (pixel) according to the embodiment of the present invention is a green pixel, it is preferable that the other pixels include at least a red pixel and a blue pixel. In addition, in a case where the film (pixel) according to the embodiment of the present invention is a cyan pixel, it is preferable that the other pixels include at least a yellow pixel and a magenta pixel.

In the color filter according to the embodiment of the present invention, the thickness of the film according to the embodiment of the present invention can be appropriately adjusted depending on the purposes. The thickness of the film is preferably 20 μm or less, more preferably 10 μm or less, and still more preferably 5 μm or less. The lower limit of the thickness of the film is preferably 0.1 μm or more, more preferably 0.2 μm or more, and still more preferably 0.3 μm or more.

In the color filter according to the embodiment of the present invention, the width of the pixel is preferably 0.5 to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 to 20 GPa and more preferably 2.5 to 15 GPa.

Each pixel included in the color filter according to the embodiment of the present invention preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 50° to 110°. The contact angle can be measured, for example, using a contact angle meter CV-DT-A Model (manufactured by Kyowa Interface Science Co., Ltd.).

In addition, it is preferable that the volume resistivity value of the pixel is high. Specifically, the volume resistivity value of the pixel is preferably 10⁹ Ω×cm or more and more preferably 10¹¹ Ω×cm or more. The upper limit is not specified, but is, for example, preferably 10¹⁴ Ω×cm or less. The volume resistivity value of the pixel can be measured, for example, using an ultrahigh resistance meter 5410 (manufactured by Advantest Corporation).

In addition, in the color filter according to the embodiment of the present invention, a protective layer may be provided on the surface of the film according to the embodiment of the present invention. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 to 10 μm and more preferably 0.1 to 5 μm. Examples of a method for forming the protective layer include a method of forming the protective layer by applying a resin composition dissolved in an organic solvent, a chemical vapor deposition method, and a method of attaching a molded resin with an adhesive. Examples of components constituting the protective layer include a (meth)acrylic resin, an ene-thiol resin, a polycarbonate resin, a poly ether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an inkjet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic fine particles, an absorber of light (for example, ultraviolet rays, near-infrared rays, and the like) having a specific wavelength, a refractive index adjusting agent, an antioxidant, an adhesive agent, and a surfactant. Examples of the organic or inorganic fine particles include polymer fine particles (for example, silicone resin fine particles, polystyrene fine particles, and melamine resin fine particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of light having a specific wavelength, a known absorber can be used. The content of these additives can be appropriately adjusted, but is preferably 0.1 to 70 mass % and still more preferably 1 to 60 mass % with respect to the total mass of the protective layer.

In addition, as the protective layer, the protective layers described in paragraphs “0073” to “0092” of JP2017-151176A can also be used.

<Method for Manufacturing Color Filter>

Next, a method for manufacturing a color filter using the coloring composition according to the embodiment of the present invention will be described. The color filter can be manufactured through a step of forming a coloring composition layer on a support using the above-described coloring composition according to the embodiment of the present invention, and a step of forming a pattern on the coloring composition layer by a photolithography method or a dry etching method. Since, in the coloring composition according to the embodiment of the present invention, generation of development residue can be suppressed, the present invention is particularly effective in a case of manufacturing a color filter in which a pattern is formed on the coloring composition layer by a photolithography method.

(Photolithography Method)

First, a case of forming a pattern by a photolithography method to manufacture a color filter will be described. This manufacturing method preferably includes a step of forming a coloring composition layer on a support using the coloring composition according to the embodiment of the present invention, a step of patternwise exposing the coloring composition layer, and a step of removing an unexposed area of the coloring composition layer by development to form a pattern (pixel). Optionally, a step (pre-baking step) of baking the coloring composition layer and a step (post-baking step) of baking the developed pattern (pixel) may be provided.

In the step of forming a coloring composition according to the embodiment of the present invention, the coloring composition layer is formed on a support using the coloring composition according to the embodiment of the present invention. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of substances, or planarize the surface of the substrate.

As a method of applying the coloring composition, a known method can be used. Examples of the known method include: a drop casting method; a slit coating method; a spray method; a roll coating method; a spin coating method; a cast coating method; a slit and spin method; a pre-wetting method (for example, a method described in JP2009-145395A); various printing methods including jet printing such as an inkjet method (for example, an on-demand method, a piezoelectric method, or a thermal method) or a nozzle jet method, flexographic printing, screen printing, gravure printing, reverse offset printing, and metal mask printing; a transfer method using a mold or the like; and a nanoimprinting method. The application method using an ink jet method is not particularly limited, and examples thereof include a method (in particular, pp. 115 to 133) described in “Extension of Use of Ink Jet—Infinite Possibilities in Patent—” (February, 2005, S.B. Research Co., Ltd.) and methods described in JP2003-262716A, JP2003-185831A, JP2003-261827A, JP2012-126830A, and JP2006-169325A. In addition, with regard to the method of applying the coloring composition, reference can be made to the description in WO2017/030174A and WO2017/018419A, the contents of which are incorporated herein by reference.

The coloring composition layer formed on the support may be dried (pre-baked). In a case of producing a film by a low-temperature process, pre-baking may not be performed. In a case where pre-baking is performed, the pre-baking temperature is preferably 150° C. or lower, more preferably 120° C. or lower, and still more preferably 110° C. or lower. The lower limit may be, for example, 50° C. or higher or 80° C. or higher. The pre-baking time is preferably 10 to 300 seconds, more preferably 40 to 250 seconds, and still more preferably 80 to 220 seconds. Pre-baking can be performed using a hot plate, an oven, or the like.

“Exposure Step”

Next, the coloring composition layer is patternwise exposed (exposing step). For example, the coloring composition layer can be patternwise exposed using a stepper exposure device or a scanner exposure device through a mask having a predetermined mask pattern. As a result, the exposed portion can be cured.

Examples of the radiation (light) which can be used during the exposure include g-rays and i-rays. In addition, light (preferably light having a wavelength of 180 to 300 nm) having a wavelength of 300 nm or less can also be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the composition layer may be irradiated with light continuously to expose the composition layer, or the composition layer may be irradiated with light in a pulse to expose the composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50000000 W/m² or more, more preferably 100000000 W/m² or more, and still more preferably 200000000 W/m² or more. In addition, the upper limit of the maximum instantaneous illuminance is preferably 1000000000 W/m² or less, more preferably 800000000 W/m² or less, and still more preferably 500000000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure amount) is, for example, preferably 0.03 to 2.5 J/cm² and more preferably 0.05 to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be usually selected from a range of 1000 W/m² to 100000 W/m² (for example, 5000 W/m², 15000 W/m², or 35000 W/m²). Appropriate conditions of each of the oxygen concentration and the exposure illuminance may be combined, and for example, a combination of the oxygen concentration of 10% by volume and the illuminance of 10000 W/m², a combination of the oxygen concentration of 35% by volume and the illuminance of 20000 W/m², or the like is available.

Next, the unexposed area of the coloring composition layer is removed by development to form a pattern (pixel). The unexposed area of the coloring composition layer can be removed by development using a developer. Thus, the coloring composition layer of the unexposed area in the exposure step is eluted into the developer, and as a result, only a photocured portion remains. As the developer, an organic alkaline developer causing no damage on a base of element, circuit, or the like is desirable. For example, the temperature of the developer is preferably 20° C. to 30° C. The development time is preferably 20 to 180 seconds. In addition, in order to further improve residues removing properties, a step of shaking the developer off per 60 seconds and supplying a new developer may be repeated multiple times.

Examples of the developer include an organic solvent and an alkaline developer, and an alkaline developer is preferably used. As the alkaline developer, an alkaline aqueous solution (alkaline developer) in which an alkaline agent is diluted with pure water is preferable. Examples of the alkaline agent include: an organic alkaline compound such as ammonia, ethylamine, diethylamine, dimethylethanolamine, diglycolamine, diethanolamine, hydroxyamine, ethylenediamine, tetramethylammonium hydroxide, tetraethylammonium hydroxide, tetrapropylammonium hydroxide, tetrabutylammonium hydroxide, ethyltrimethylammonium hydroxide, benzyltrimethylammonium hydroxide, dimethyl bis(2-hydroxyethyl)ammonium hydroxide, choline, pyrrole, piperidine, and 1,8-diazabicyclo[5.4.0]-7-undecene; and an inorganic alkaline compound such as sodium hydroxide, potassium hydroxide, sodium carbonate, sodium bicarbonate, sodium silicate, and sodium metasilicate. In consideration of environmental aspects and safety aspects, the alkaline agent is preferably a compound having a high molecular weight. The concentration of the alkaline agent in the alkaline aqueous solution is preferably 0.001 to 10 mass % and more preferably 0.01 to 1 mass %. In addition, the developer may further contain a surfactant. Examples of the surfactant include the surfactants described above. Among these, a nonionic surfactant is preferable. From the viewpoint of easiness of transport, storage, and the like, the developer may be obtained by temporarily preparing a concentrated solution and diluting the concentrated solution to a necessary concentration during use. The dilution factor is not particularly limited and, for example, can be set to be in a range of 1.5 to 100 times. In addition, it is also preferable to wash (rinse) with pure water after development. In addition, it is preferable that the rinsing is performed by supplying a rinsing liquid to the coloring composition layer after development while rotating the support on which the coloring composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to perform an additional exposure treatment or a heat treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The film after development is post-baked continuously or batchwise using a heating unit such as a hot plate, a convection oven (hot air circulation dryer), and a high-frequency heater under the above-described conditions. In a case of performing the additional exposure treatment, light used for the exposure is preferably light having a wavelength of 400 nm or less. In addition, the additional exposure treatment may be carried out by the method described in KR10-2017-0122130A.

(Dry Etching Method)

Next, a case of forming a pattern by a dry etching method to manufacture a color filter will be described. Pattern formation by a dry etching method preferably includes a step of forming a coloring composition layer on a support using the coloring composition according to the embodiment of the present invention and curing the entire coloring composition layer to form a cured composition layer, a step of forming a photoresist layer on the cured composition layer, a step of patternwise exposing the photoresist layer and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heat treatment after exposure and a heat treatment after development (post-baking treatment) are performed. The details of the pattern formation by the dry etching method can be found in paragraphs “0010” to “0067” of JP2013-064993A, the content of which is incorporated herein by reference.

<Solid-State Imaging Element>

The solid-state imaging element according to the embodiment of the present invention has the film according to the embodiment of the present invention. The configuration of the solid-state imaging element according to the embodiment of the present invention is not particularly limited as long as the solid-state imaging element is configured to include the film according to the embodiment of the present invention and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving portion of the photodiodes on the photodiodes and the transfer electrodes; have a device-protective film formed of silicon nitride or the like, which is formed to cover the entire surface of the light-shielding film and the light receiving portion of the photodiodes, on the light-shielding film; and have a color filter on the device-protective film. Furthermore, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. In this case, it is preferable that the partition wall has a lower refractive index than each colored pixel. Examples of an imaging device having such a structure include the devices described in JP2012-227478A, JP2014-179577A, WO2018/043654A, and US2018/0040656A. An imaging device including the solid-state imaging element according to the embodiment of the present invention can also be used as a vehicle camera or a surveillance camera, in addition to a digital camera or electronic apparatus (mobile phones or the like) having an imaging function.

<Image Display Device>

The image display device according to the embodiment of the present invention has the film according to the embodiment of the present invention. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989)”, and the like. In addition, the details of a liquid crystal display device can be found in, for example, “Next-Generation Liquid Crystal Display Techniques (Edited by Tatsuo Uchida, Kogyo Chosakai Publishing Co., Ltd., published in 1994)”. The liquid crystal display device to which the present invention is applicable is not particularly limited. For example, the present invention is applicable to various liquid crystal display devices described in “Next-Generation Liquid Crystal Display Techniques”.

### EXAMPLES

Hereinafter, the present invention will be described in detail using Examples. Materials, used amounts, proportions, treatment details, treatment procedures, and the like shown in the following examples can be appropriately changed within a range not departing from the scope of the present invention. Accordingly, the scope of the present invention is not limited to the following specific examples.

<Method for Measuring Energy Level of Lowest Unoccupied Molecular Orbital (LUMO) and Energy Level of Highest Occupied Molecular Orbital (HOMO) of Green Pigment and Compound A>

The energy level of the highest occupied molecular orbital (HOMO) of the green pigment and the compound A was measured using an atmospheric photoelectron spectrometer AC-3 manufactured by Hitachi High-Tech Corporation. The energy level of the lowest unoccupied molecular orbital (LUMO) of the green pigment and the compound A was calculated from the absorption edge of the diffuse-reflect spectrum using V-7200 (with an integrating sphere) manufactured by JASCO Corporation.

<Method for Measuring Amount of Green Pigment and Compound a Dissolved>

To 100 g of propylene glycol methyl ether acetate at 25° C., 0.01 g, 0.1 g, or 1 g of the compound A or the green pigment was added, respectively, and the mixture was stirred at room temperature for 15 minutes, allowed to stand for 15 minutes. Thereafter, the presence or absence of insoluble matter was visually confirmed, and the amount dissolved in propylene glycol methyl ether acetate was measured. The evaluation standard is as follows.

A: dissolved amount was 1.0 g or more.

B: dissolved amount was 0.01 g or more and less than 1.0 g.

C: dissolved amount was less than 0.01 g.

<Method for Measuring Specific Absorbance of Green Pigment and Compound A>

The compound A was dissolved in toluene and the green pigment was dissolved in methanesulfonic acid, the concentration thereof was adjusted such that the maximum absorbance at a wavelength of 450 to 800 nm was 1.0, and the absorbance of the solution at 25° C. was calculated based on the following expression (A_{λ}) using a cell having an optical path length of 1 cm.

E=A/(c×l) (A_{λ})

In the expression (A_{λ}), E represents the specific absorbance of the compound A or the green pigment at the maximum absorption wavelength of 450 to 800 nm, A represents an absorbance of the compound A or the green pigment at the maximum absorption wavelength of 450 to 800 nm, 1 represents a cell length in units of cm, and c represents a concentration of the compound A or the green pigment in a solution, in units of mg/ml.

The compound A and the green pigment used in Examples are as follows.

(Green Pigment)

TABLE 1

| Type of green | HOMO | LUMO | Dissolved | Specific |
|---|---|---|---|---|
| pigment | (eV) | (eV) | amount | absorbance |
| PG58 | −5.8 | −4.3 | C | 65 |
| PG36 | −5.9 | −4.4 | C | 60 |
| PG7 | −6.2 | −4.7 | C | 55 |
| SQ1 | −6.9 | −5.4 | C | 75 |

PG58: C. I. Pigment Green 58 (halogenated phthalocyanine compound)
PG36: C. I. Pigment Green 36 (halogenated phthalocyanine compound)
PG7: C. I. Pigment Green 7 (halogenated phthalocyanine compound)
SQl: compound having the following structure (squarylium compound)

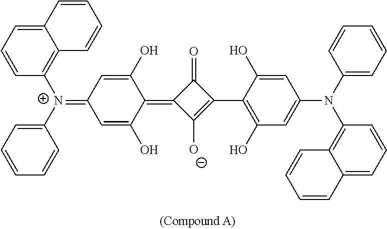 [SMILES: O=C1C(=C2C(O)=CC(=[N+](c3ccccc3)c3cccc4ccccc34)C=C2O)C([O-])=C1c1c(O)cc(N(c2ccccc2)c2cccc3ccccc23)cc1O]

TABLE 2

| Type of | HOMO | LUMO | Dissolved | Specific |
|---|---|---|---|---|
| compound A | (eV) | (eV) | amount | absorbance |
| A-11 | −6.7 | −3.9 | B | 7 |
| A-12 | −6.8 | −4.0 | B | 3 |
| A-13 | −6.4 | −3.7 | A | 2 |
| A-21 | −6.0 | −3.7 | A | 5 |
| A-22 | −5.7 | −3.4 | A | 10 |
| A-23 | −6.3 | −3.6 | B | 15 |
| A-31 | −6.2 | −3.5 | B | 15 |
| A-41 | −6.4 | −3.9 | A | 10 |
| A-51 | −6.1 | −3.9 | B | 2 |
| A-61 | −5.3 | −4.2 | B | 15 |
| A-62 | −5.5 | −4.4 | B | 10 |
| A-71 | −6.3 | −4.3 | B | 30 |

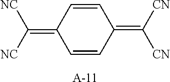

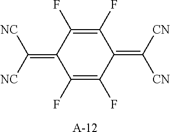

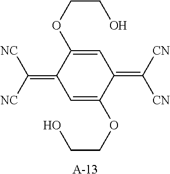

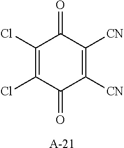

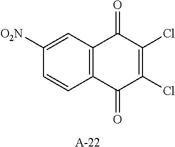 [SMILES: O=C1C(Cl)=C(Cl)C(=O)c2cc([N+](=O)[O-])ccc21 ; "A-22"]

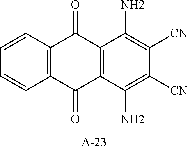

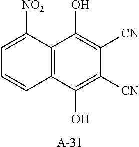

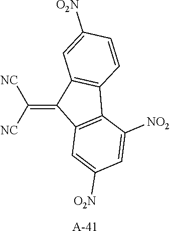

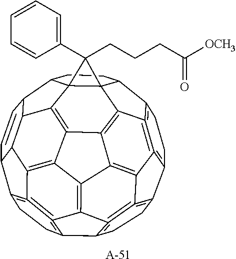

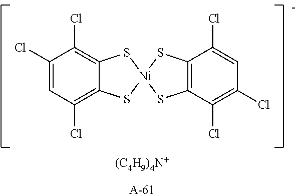

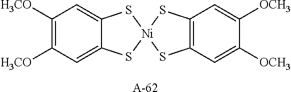

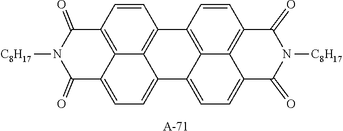

<Preparation of Pigment Dispersion Liquid>

[Dispersion Liquids G1 to G30 and Comparative Dispersion Liquids G1 to G6]

Raw materials described in the following tables were mixed, and then 230 parts by mass of zirconia beads having a diameter of 0.3 mm were added thereto to perform a dispersion treatment for 5 hours using a paint shaker. The beads were separated by filtration, and a dispersion liquid was produced. The numerical values described in the following table indicate parts by mass. The proportion (parts by mass) of the compound A with respect to 100 parts by mass of the green pigment and the difference (LUMO_{B}−LUMO_{A}) between the energy level LUMO_{B} of the lowest unoccupied molecular orbital of the green pigment and the energy level LUMO_{A} of the lowest unoccupied molecular orbital of the compound A are also described. Each value of the blending amounts of resins C-1 and C-2 is the value of the blending amount in a propylene glycol methyl ether acetate (PGMEA) solution having a solid content of 20 mass %.

TABLE 3

| | | | | | | | | | | | | | | | | | Proportion of compound | |
|---|---|---|---|---|---|---|---|---|---|---|---|---|---|---|---|---|---|---|
| | | | | | | | | | | | | | Com- | | | | A with respect | |
| Pigment | Colorant | | | | | | | | | | | Pigment | pound | | | | to 100 parts by mass | LUMO_{B} − |
| dispersion | Green pigment | | | | Yellow pigment | | | | | | | derivative | A | Resin | | Solvent | of green pigment | LUMO_{A} |
| liquid | PG58 | PG36 | PG7 | SQ1 | PY138 | PY139 | PY185 | PY150 | PY215 | Yellow 1 | Yellow 2 | Derivative 1 | A-11 | C-1 | C-2 | (PGMEA) | (part by mass) | (eV) |
| Dispersion | 13.5 | | | | | | | | | | | 1.5 | 0.02 | 25 | | 59.98 | 0.15 | −0.4 |
| liquid G1 | | | | | | | | | | | | | | | | | | |
| Dispersion | 13.5 | | | | | | | | | | | 1.5 | 0.03 | 25 | | 59.97 | 0.22 | −0.4 |
| liquid G2 | | | | | | | | | | | | | | | | | | |
| Dispersion | 13.5 | | | | | | | | | | | 1.5 | 0.15 | 25 | | 59.85 | 1.1 | −0.4 |
| liquid G3 | | | | | | | | | | | | | | | | | | |
| Dispersion | 13.5 | | | | | | | | | | | 1.5 | 0.4 | 25 | | 59.6 | 3.0 | −0.4 |
| liquid G4 | | | | | | | | | | | | | | | | | | |
| Dispersion | 13.5 | | | | | | | | | | | 1.5 | 0.5 | 25 | | 59.5 | 3.7 | −0.4 |
| liquid G5 | | | | | | | | | | | | | | | | | | |
| Dispersion | 13.5 | | | | | | | | | | | 1.5 | 0.75 | 25 | | 59.25 | 5.6 | −0.4 |
| liquid G6 | | | | | | | | | | | | | | | | | | |
| Dispersion | | 13.5 | | | | | | | | | | 1.5 | 0.15 | 25 | | 59.85 | 1.1 | −0.5 |
| liquid G7 | | | | | | | | | | | | | | | | | | |
| Dispersion | | | 13.5 | | | | | | | | | 1.5 | 0.15 | 25 | | 59.85 | 1.1 | −0.8 |
| liquid G8 | | | | | | | | | | | | | | | | | | |
| Dispersion | 9 | | | | 4.5 | | | | | | | 1.5 | 0.01 | 25 | | 59.99 | 0.1 | −0.4 |
| liquid G9 | | | | | | | | | | | | | | | | | | |
| Dispersion | 9 | | | | 4.5 | | | | | | | 1.5 | 0.03 | 25 | | 59.97 | 0.3 | −0.4 |
| liquid G10 | | | | | | | | | | | | | | | | | | |
| Dispersion | 9 | | | | 4.5 | | | | | | | 1.5 | 0.15 | 25 | | 59.85 | 1.7 | −0.4 |
| liquid G11 | | | | | | | | | | | | | | | | | | |
| Dispersion | 9 | | | | 4.5 | | | | | | | 1.5 | 0.25 | 25 | | 59.75 | 2.8 | −0.4 |
| liquid G12 | | | | | | | | | | | | | | | | | | |
| Dispersion | 9 | | | | 4.5 | | | | | | | 1.5 | 0.4 | 25 | | 59.6 | 4.4 | −0.4 |
| liquid G13 | | | | | | | | | | | | | | | | | | |
| Dispersion | 9 | | | | 4.5 | | | | | | | 1.5 | 0.75 | 25 | | 59.25 | 8.3 | −0.4 |
| liquid G14 | | | | | | | | | | | | | | | | | | |
| Dispersion | | 9 | | | 4.5 | | | | | | | 1.5 | 0.15 | 25 | | 59.85 | 1.7 | −0.5 |
| liquid G15 | | | | | | | | | | | | | | | | | | |
| Dispersion | | | 9 | | 4.5 | | | | | | | 1.5 | 0.15 | 25 | | 59.85 | 1.7 | −0.8 |
| liquid G16 | | | | | | | | | | | | | | | | | | |
| Dispersion | 9 | | | | | 4.5 | | | | | | 1.5 | 0.15 | 25 | | 59.85 | 1.7 | −0.4 |
| liquid G17 | | | | | | | | | | | | | | | | | | |
| Dispersion | 9 | | | | | | 4.5 | | | | | 1.5 | 0.15 | 25 | | 59.85 | 1.7 | −0.4 |
| liquid G18 | | | | | | | | | | | | | | | | | | |
| Dispersion | | 9 | | | | 4.5 | | | | | | 1.5 | 0.15 | 25 | | 59.85 | 1.7 | −0.5 |
| liquid G19 | | | | | | | | | | | | | | | | | | |
| Dispersion | | 9 | | | | | 4.5 | | | | | 1.5 | 0.15 | 25 | | 59.85 | 1.7 | −0.5 |
| liquid G20 | | | | | | | | | | | | | | | | | | |
| Dispersion | 9 | | | | | | | 4.5 | | | | 1.5 | 0.15 | 25 | | 59.85 | 1.7 | −0.4 |
| liquid G21 | | | | | | | | | | | | | | | | | | |
| Dispersion | 11 | | | | 2.5 | | | | | | | 1.5 | 0.15 | 25 | | 59.85 | 1.4 | −0.4 |
| liquid G22 | | | | | | | | | | | | | | | | | | |
| Dispersion | 12 | | | | 1.5 | | | | | | | 1.5 | 0.15 | 25 | | 59.85 | 1.3 | −0.4 |
| liquid G23 | | | | | | | | | | | | | | | | | | |
| Dispersion | 7.5 | | | | 6 | | | | | | | 1.5 | 0.15 | 25 | | 59.85 | 2.0 | −0.4 |
| liquid G24 | | | | | | | | | | | | | | | | | | |
| Dispersion | 4.5 | 4.5 | | | 2.5 | | 2 | | | | | 1.5 | 0.15 | 25 | | 59.85 | 1.7 | −0.5 |
| liquid G25 | | | | | | | | | | | | | | | | | | |
| Dispersion | 4.5 | | | 4.5 | 4.5 | | | | | | | 1.5 | 0.15 | 25 | | 59.85 | 1.7 | −1.0 |
| liquid G26 | | | | | | | | | | | | | | | | | | |
| Dispersion | 9 | | | | 4.5 | | | | | | | 1.5 | 0.15 | | 25 | 59.85 | 1.7 | −0.4 |
| liquid G27 | | | | | | | | | | | | | | | | | | |
| Dispersion | | 9 | | | | | | | 4.5 | | | 1.5 | 0.15 | 25 | | 59.85 | 1.7 | −0.4 |
| liquid G28 | | | | | | | | | | | | | | | | | | |
| Dispersion | | 9 | | | | | | | | 4.5 | | 1.5 | 0.15 | 25 | | 59.85 | 1.7 | −0.4 |
| liquid G29 | | | | | | | | | | | | | | | | | | |
| Dispersion | | 9 | | | | | | | | | 4.5 | 1.5 | 0.15 | 25 | | 59.85 | 1.7 | −0.4 |
| liquid G30 | | | | | | | | | | | | | | | | | | |
| Comparative | 13.5 | | | | | | | | | | | 1.5 | 0 | 25 | | 60 | — | — |
| dispersion | | | | | | | | | | | | | | | | | | |
| liquid G1 | | | | | | | | | | | | | | | | | | |
| Comparative | | 13.5 | | | | | | | | | | 1.5 | 0 | 25 | | 60 | — | — |
| dispersion | | | | | | | | | | | | | | | | | | |
| liquid G2 | | | | | | | | | | | | | | | | | | |
| Comparative | | | 13.5 | | | | | | | | | 1.5 | 0 | 25 | | 60 | — | — |
| dispersion | | | | | | | | | | | | | | | | | | |
| liquid G3 | | | | | | | | | | | | | | | | | | |
| Comparative | 9 | | | | 4.5 | | | | | | | 1.5 | 0 | 25 | | 60 | — | — |
| dispersion | | | | | | | | | | | | | | | | | | |
| liquid G4 | | | | | | | | | | | | | | | | | | |
| Comparative | 9 | | | | | 4.5 | | | | | | 1.5 | 0 | 25 | | 60 | — | — |
| dispersion | | | | | | | | | | | | | | | | | | |
| liquid G5 | | | | | | | | | | | | | | | | | | |
| Comparative | | 9 | | | | | 4.5 | | | | | 1.5 | 0 | 25 | | 60 | — | — |
| dispersion | | | | | | | | | | | | | | | | | | |
| liquid G6 | | | | | | | | | | | | | | | | | | |

Details of the materials other than the green pigment and the compound A, which are indicated by the abbreviations in the above table, are as follows.

(Yellow Pigment)

PY139: C. I. Pigment Yellow 139 (isoindoline compound)

PY185: C. I. Pigment Yellow 185 (isoindoline compound)

PY138: C. I. Pigment Yellow 138 (quinophthalone compound)

PY150: C. I. Pigment Yellow 150 (azo compound)

PY215: C. I. Pigment Yellow 215 (pteridin compound)

Yellow1: compound having the following structure

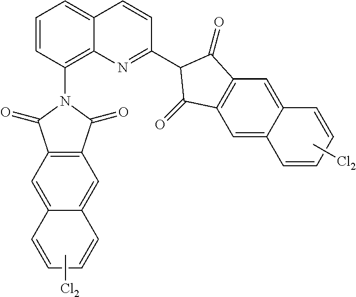

Yellow2: compound having the following structure

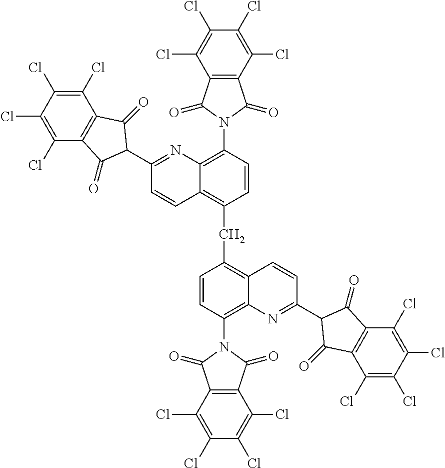 [SMILES: O=C1c2c(Cl)c(Cl)c(Cl)c(Cl)c2C(=O)C1c1ccc2c(Cc3ccc(N4C(=O)c5c(Cl)c(Cl)c(Cl)c(Cl)c5C4=O)c4nc(C5C(=O)c6c(Cl)c(Cl)c(Cl)c(Cl)c6C5=O)ccc34)ccc(N3C(=O)c4c(Cl)c(Cl)c(Cl)c(Cl)c4C3=O)c2n1]

(Pigment Derivative)

Derivative 1: compound having the following structure (the amount of the derivative 1 dissolved in 100 g of propylene glycol methyl ether acetate at 25° C. is less than 0.01 g)

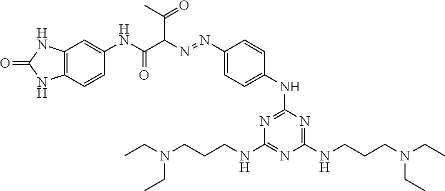 [SMILES: CCN(CC)CCCNc1nc(NCCCN(CC)CC)nc(Nc2ccc(/N=N/C(C(C)=O)C(=O)Nc3ccc4[nH]c(=O)[nH]c4c3)cc2)n1]

(Resin)

Resin C-1: 20 mass % of propylene glycol methyl ether acetate (PGMEA) solution of a resin having the following structure (the numerical value described together with the main chain indicates a molar ratio, and the numerical value described together with the side chain indicates the number of repeating units, Mw=20000)

Resin C-2: 20 mass % of propylene glycol methyl ether acetate (PGMEA) solution of a resin having the following structure (the numerical value described together with the main chain indicates a molar ratio, and the numerical value described together with the side chain indicates the number of repeating units, Mw=18000)

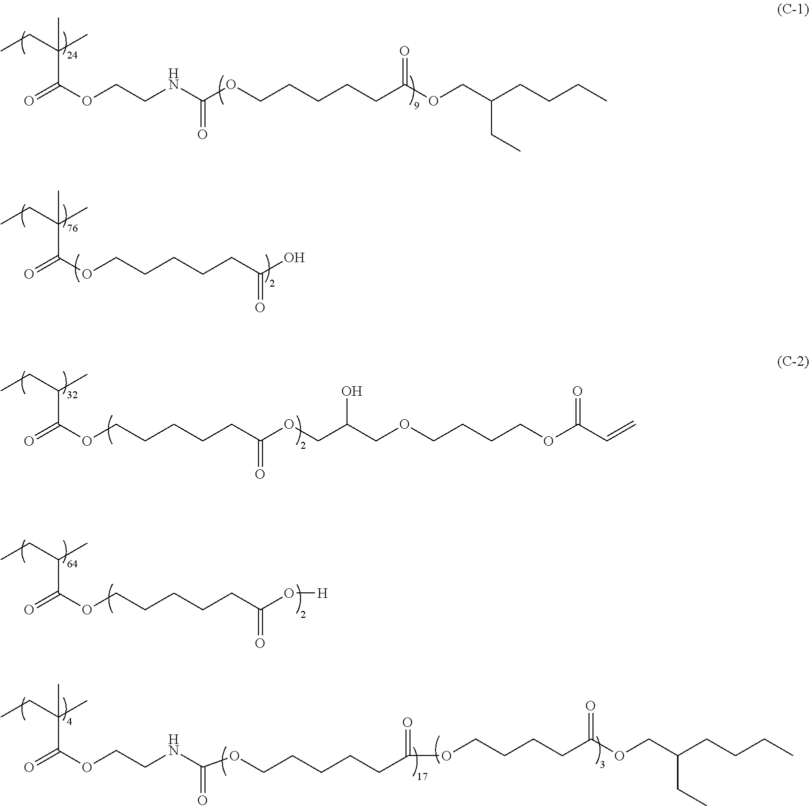

(Solvent)

PGMEA: propylene glycol methyl ether acetate

[Dispersion Liquids G31 to G41]

Dispersion liquids G31 to G41 were prepared in the same manner as in the dispersion liquid Gil, except that, in the dispersion liquid Gil, the compound A was changed to a compound of the type shown in the table below. The proportion (parts by mass) of the compound A with respect to 100 parts by mass of the green pigment and the difference (LUMO_{B}−LUMO_{A}) between the energy level LUMO_{B} of the lowest unoccupied molecular orbital of the green pigment and the energy level LUMO_{A} of the lowest unoccupied molecular orbital of the compound A are also described.

TABLE 4

| | | Proportion of | |
|---|---|---|---|
| | | compound A with | |
| | | respect to 100 parts | |
| Pigment | Type of | by mass of | LUMO_{B} − |
| dispersion | compound | green pigment | LUMO_{A} |
| liquid | A | (part by mass) | (eV) |
| Dispersion | A-12 | 1.7 | −0.3 |
| liquid G31 | | | |
| Dispersion | A-13 | 1.7 | −0.6 |
| liquid G32 | | | |
| Dispersion | A-21 | 1.7 | −0.6 |
| liquid G33 | | | |
| Dispersion | A-22 | 1.7 | −0.9 |
| liquid G34 | | | |
| Dispersion | A-23 | 1.7 | −0.7 |
| liquid G35 | | | |
| Dispersion | A-31 | 1.7 | −0.8 |
| liquid G36 | | | |
| Dispersion | A-41 | 1.7 | −0.4 |
| liquid G37 | | | |
| Dispersion | A-51 | 1.7 | −0.4 |
| liquid G38 | | | |
| Dispersion | A-61 | 1.7 | −0.1 |
| liquid G39 | | | |
| Dispersion | A-62 | 1.7 | 0.2 |
| liquid G40 | | | |
| Dispersion | A-71 | 1.7 | 0.0 |
| liquid G41 | | | |

Preparation of Coloring Composition>

Raw materials described in the following tables were mixed to prepare a coloring composition. The value of colorant concentration in the following tables is the value of the content of the colorant in the total solid content of the coloring composition. In addition, the value of the blending amounts of a resin C-3 is the value of the blending amount in a PGMEA solution having a solid content of 20 mass %. The value of the blending amounts of a surfactant 1-1 is the value of the blending amount in a PGMEA solution having a solid content of 1 mass %.

TABLE 5

| | Pigment | | | | Polymerizable | | Photopolymer- | | | | Polymerization | | | | |
|---|---|---|---|---|---|---|---|---|---|---|---|---|---|---|---|
| | dispersion liquid | | Resin | | compound | | ization initiator | | Surfactant | | inhibitor | | Solvent | | Concen- |
| | | Part | | Part | | Part | | Part | | Part | | Part | | Part | tration of |
| | | by | | by | | by | | by | | by | | by | | by | colorant |
| | Type | mass | Type | mass | Type | mass | Type | mass | Type | mass | Type | mass | Type | mass | (mass %) |
| Example | Dispersion | 65 | C-3 | 5.9 | F-1 | 2.6 | G-1 | 0.7 | I-1 | 5.0 | J-1 | 0.01 | K-1 | 20.8 | 50 |
| 1 | liquid G1 | | | | | | | | | | | | | | |
| Example | Dispersion | 65 | C-3 | 5.9 | F-1 | 2.6 | G-1 | 0.7 | I-1 | 5.0 | J-1 | 0.01 | K-1 | 20.8 | 50 |
| 2 | liquid G2 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 3 | liquid G3 | | | | | | | | | | | | | | |
| Example | Dispersion | 65 | C-3 | 4.7 | F-1 | 2.6 | G-1 | 0.7 | I-1 | 5.0 | J-1 | 0.01 | K-1 | 22.0 | 50 |
| 4 | liquid G4 | | | | | | | | | | | | | | |
| Example | Dispersion | 65 | C-3 | 4.3 | F-1 | 2.6 | G-1 | 0.7 | I-1 | 5.0 | J-1 | 0.01 | K-1 | 22.4 | 50 |
| 5 | liquid G5 | | | | | | | | | | | | | | |
| Example | Dispersion | 65 | C-3 | 3.5 | F-1 | 2.6 | G-1 | 0.7 | I-1 | 5.0 | J-1 | 0.01 | K-1 | 23.2 | 50 |
| 6 | liquid G6 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 7 | liquid G7 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 8 | liquid G8 | | | | | | | | | | | | | | |
| Example | Dispersion | 65 | C-3 | 5.9 | F-1 | 2.6 | G-1 | 0.7 | I-1 | 5.0 | J-1 | 0.01 | K-1 | 20.8 | 50 |
| 9 | liquid G9 | | | | | | | | | | | | | | |
| Example | Dispersion | 65 | C-3 | 5.9 | F-1 | 2.6 | G-1 | 0.7 | I-1 | 5.0 | J-1 | 0.01 | K-1 | 20.8 | 50 |
| 10 | liquid G10 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 11 | liquid G11 | | | | | | | | | | | | | | |
| Example | Dispersion | 65 | C-3 | 5.1 | F-1 | 2.6 | G-1 | 0.7 | I-1 | 5.0 | J-1 | 0.01 | K-1 | 21.6 | 50 |
| 12 | liquid G12 | | | | | | | | | | | | | | |
| Example | Dispersion | 65 | C-3 | 4.7 | F-1 | 2.6 | G-1 | 0.7 | I-1 | 5.0 | J-1 | 0.01 | K-1 | 22.0 | 50 |
| 13 | liquid G13 | | | | | | | | | | | | | | |
| Example | Dispersion | 65 | C-3 | 3.5 | F-1 | 2.6 | G-1 | 0.7 | I-1 | 5.0 | J-1 | 0.01 | K-1 | 23.2 | 50 |
| 14 | liquid G14 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 15 | liquid G15 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 16 | liquid G16 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 17 | liquid G17 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 18 | liquid G18 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 19 | liquid G19 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 20 | liquid G20 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 21 | liquid G21 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 22 | liquid G22 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 23 | liquid G23 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 24 | liquid G24 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 25 | liquid G25 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 26 | liquid G26 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 27 | liquid G27 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 28 | liquid G28 | | | | | | | | | | | | | | |

TABLE 6

| | Pigment | | | | Polymerizable | | Photopolymer- | | | | Polymerization | | | | |
|---|---|---|---|---|---|---|---|---|---|---|---|---|---|---|---|
| | dispersion liquid | | Resin | | compound | | ization initiator | | Surfactant | | inhibitor | | Solvent | | Concen- |
| | | Part | | Part | | Part | | Part | | Part | | Part | | Part | tration of |
| | | by | | by | | by | | by | | by | | by | | by | colorant |
| | Type | mass | Type | mass | Type | mass | Type | mass | Type | mass | Type | mass | Type | mass | (mass %) |
| Example | Dispersion | 65 | C-3 | 5.5 | F-1 | 2.6 | G-1 | 0.7 | I-1 | 5.0 | J-1 | 0.01 | K-1 | 21.2 | 50 |
| 29 | liquid G29 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 30 | liquid G30 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 31 | liquid G31 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 32 | liquid G32 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 33 | liquid G33 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 34 | liquid G34 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 35 | liquid G35 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 36 | liquid G36 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 37 | liquid G37 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 38 | liquid G38 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 39 | liquid G39 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 40 | liquid G40 | | | | | | | | | | | | | | |
| Example | Dispersion | 65 | C-3 | 5.5 | F-1 | 2.6 | G-1 | 0.7 | I-1 | 5.0 | J-1 | 0.01 | K-1 | 21.2 | 50 |
| 41 | liquid G41 | | | | | | | | | | | | | | |
| Example | Dispersion | 50 | C-3 | 8.0 | F-1 | 4.0 | G-1 | 1.0 | I-1 | 5.0 | J-1 | 0.01 | K-1 | 32.0 | 40 |
| 42 | liquid G11 | | | | | | | | | | | | | | |
| Example | Dispersion | 50 | C-3 | 15.0 | F-1 | 8.0 | G-1 | 1.0 | I-1 | 5.0 | J-1 | 0.01 | K-1 | 21.0 | 30 |
| 43 | liquid G11 | | | | | | | | | | | | | | |
| Example | Dispersion | 65 | C-3 | 5.5 | F-1 | 2.6 | G-1 | 0.4 | I-1 | 5.0 | J-1 | 0.01 | K-1 | 21.2 | 50 |
| 44 | liquid G11 | | | | | | G-2 | 0.3 | | | | | | | |
| Example | Dispersion | 65 | C-3 | 5.5 | F-1 | 2.6 | G-1 | 0.7 | I-1 | 5.0 | J-1 | 0.01 | K-1 | 10.6 | 50 |
| 45 | liquid G11 | | | | | | | | | | | | K-2 | 10.6 | |
| Example | Dispersion | 65 | C-3 | 3.0 | F-1 | 2.6 | G-1 | 0.7 | I-1 | 5.0 | J-1 | 0.01 | K-1 | 21.2 | 50 |
| 46 | liquid G11 | | C-2 | 2.5 | | | | | | | | | | | |
| Example | Dispersion | 65 | C-3 | 5.5 | F-1 | 1.3 | G-1 | 0.7 | I-1 | 5.0 | J-1 | 0.01 | K-1 | 21.2 | 50 |
| 47 | liquid G11 | | | | F-2 | 1.3 | | | | | | | | | |
| Com- | Comparative | 65 | C-3 | 5.9 | F-1 | 2.6 | G-1 | 0.7 | I-1 | 5.0 | J-1 | 0.01 | K-1 | 20.7 | 50 |
| parative | dispersion | | | | | | | | | | | | | | |
| example 1 | liquid G1 | | | | | | | | | | | | | | |
| Com- | Comparative | 65 | C-3 | 5.9 | F-1 | 2.6 | G-1 | 0.7 | I-1 | 5.0 | J-1 | 0.01 | K-1 | 20.7 | 50 |
| parative | dispersion | | | | | | | | | | | | | | |
| example 2 | liquid G2 | | | | | | | | | | | | | | |
| Com- | Comparative | 65 | C-3 | 5.9 | F-1 | 2.6 | G-1 | 0.7 | I-1 | 5.0 | J-1 | 0.01 | K-1 | 20.7 | 50 |
| parative | dispersion | | | | | | | | | | | | | | |
| example 3 | liquid G3 | | | | | | | | | | | | | | |
| Com- | Comparative | 65 | C-3 | 5.9 | F-1 | 2.6 | G-1 | 0.7 | I-1 | 5.0 | J-1 | 0.01 | K-1 | 20.7 | 50 |
| parative | dispersion | | | | | | | | | | | | | | |
| example 4 | liquid G4 | | | | | | | | | | | | | | |
| Com- | Comparative | 65 | C-3 | 5.9 | F-1 | 2.6 | G-1 | 0.7 | I-1 | 5.0 | J-1 | 0.01 | K-1 | 20.7 | 50 |
| parative | dispersion | | | | | | | | | | | | | | |
| example 5 | liquid G5 | | | | | | | | | | | | | | |
| Com- | Comparative | 65 | C-3 | 5.9 | F-1 | 2.6 | G-1 | 0.7 | I-1 | 5.0 | J-1 | 0.01 | K-1 | 20.7 | 50 |
| parative | dispersion | | | | | | | | | | | | | | |
| example 6 | liquid G6 | | | | | | | | | | | | | | |
| Com- | Comparative | 50 | C-3 | 8.5 | F-1 | 4.0 | G-1 | 1.0 | I-1 | 5.0 | J-1 | 0.01 | K-1 | 31.5 | 40 |
| parative | dispersion | | | | | | | | | | | | | | |
| example 7 | liquid G4 | | | | | | | | | | | | | | |
| Com- | Comparative | 50 | C-3 | 15.5 | F-1 | 8.0 | G-1 | 1.0 | I-1 | 5.0 | J-1 | 0.01 | K-1 | 20.5 | 30 |
| parative | dispersion | | | | | | | | | | | | | | |
| example 8 | liquid G4 | | | | | | | | | | | | | | |

Details of the materials indicated by the abbreviations in the above tables are as follows.

(Pigment Dispersion Liquid)

Dispersion liquids G1 to G41 and comparative dispersion liquids G1 to G6: dispersion liquids G1 to G41 and comparative dispersion liquids G1 to G6 described above

(Resin)

Resin C-3: 20 mass % of propylene glycol methyl ether acetate (PGMEA) solution of a resin having the following structure (the numerical value described together with the main chain indicates a molar ratio, Mw=11000)

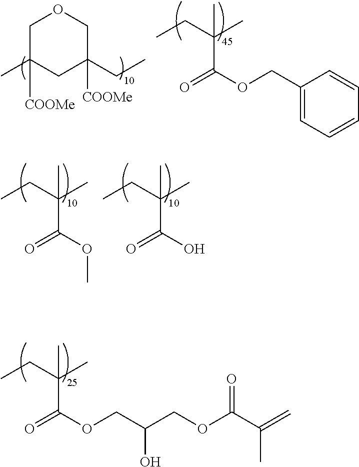

(Polymerizable Compound)

Polymerizable compound F-1: dipentaerythritol hexaacrylate (manufactured by Nippon Kayaku Co., Ltd., KAYARAD DPHA, molecular weight: 578)

Polymerizable compound F-2: ethylene oxide-modified product of trimethylolpropane polyacrylate (manufactured by TOAGOSEI CO., LTD., ARONIX M-350)

(Photopolymerization Initiator)

Photopolymerization initiator G-1: IRGACURE-OXE02 (manufactured by BASF)

Photopolymerization initiator G-2: IRGACURE-369 (manufactured by BASF)

(Surfactant)

Surfactant 1-1: 1 mass % PGMEA solution of a mixture having the following structure (Mw=14000; in the following formula, “%” representing the proportion of a repeating unit is mol %)

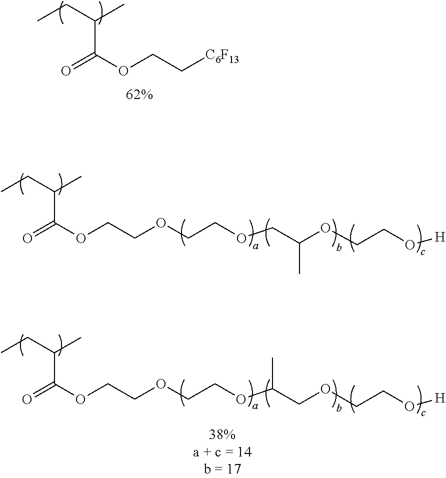

(Polymerization Inhibitor)

Polymerization inhibitor J-1: p-methoxyphenol

(Solvent)

K-1: propylene glycol methyl ether acetate

K-2: propylene glycol methyl ether

<Evaluation of Storage Stability>

A viscosity (V₁) of the coloring composition immediately after production obtained above was measured with “RE-85L” manufactured by TOKI SANGYO CO., LTD. This coloring composition was allowed to stand for 14 days under a temperature condition of 23° C., and then a viscosity (V₂) thereof was measured. The thickening rate was calculated from the following expression, and the storage stability was evaluated according to the following evaluation standard. The viscosity of the coloring composition was measured in a state in which the temperature was adjusted to 23° C. The evaluation standard is as follows, and the evaluation results are shown in the table below.

Thickening rate (%)={(Viscosity (V₂)−Viscosity (V₁))/Viscosity (V₁)}×100

A: thickening rate was less than 5%.

B: thickening rate was 5% or more and less than 10%.

C: thickening rate was 10% or more and less than 20%.

D: thickening rate was 20% or more.

<Evaluation of Developability>

A CT-4000L solution (manufactured by Fujifilm Electronic Materials Co., Ltd.; transparent base coat agent) was applied to a silicon wafer so that the thickness of a dried film was 0.1 μm, and dried to form a transparent film, and the heat treatment was performed at 220° C. for 5 minutes.

Each coloring composition was applied to the transparent film formed on the silicon wafer using a spin coating method, and then the coloring composition was heated at 100° C. for 2 minutes using a hot plate to obtain a coloring composition layer having a film thickness of 0.6 μm.

Next, using an i-ray stepper exposure device FPA-3000 i5+ (manufactured by Canon Corporation), the coloring composition layer was irradiated with light having a wavelength of 365 nm through a mask pattern in which each of the square pixels with a side length of 1.1 μm was arranged on the substrate in a region of 4 mm×3 mm to perform exposure thereon with an exposure amount of 500 mJ/cm².

Next, the silicon wafer on which the coloring composition layer after the exposure was formed was placed on a horizontal rotary table of a spin-shower developing machine (DW-30 Type, manufactured by Chemitronics Co., Ltd.), and subjected to a puddle development at 23° C. for 60 seconds using a developer (CD-2000, manufactured by Fujifilm Electronic Materials Co., Ltd.). Next, while rotating the silicon wafer at a rotation speed of 50 r.p.m., the silicon wafer was rinsed by supplying pure water from above the center of rotation in a shower shape from an ejection nozzle, and then spray-dried to form a colored pattern (pixel).

The silicon wafer on which the colored pattern was formed was observed using a length measuring scanning electron microscope (SEM) (S-7800H, manufactured by Hitachi, Ltd.) at a magnification of 30000 times above the silicon wafer, and the presence or absence of development residue in the unexposed area was examined. The evaluation standard is as follows, and the evaluation results are shown in the table below. Grains of 0.1 μm or more found in the unexposed area by SEM were defined as the development residue.

A: no development residue was observed in the unexposed area.

B: 1 to 3 development residues were observed in 1.1 μm square of the unexposed area.

C: 4 to 10 development residues were observed in 1.1 μm square of the unexposed area.

D: 11 or more development residues were observed in 1.1 μm square of the unexposed area.

TABLE 7

| | Evaluation | |
|---|---|---|
| | Storage stability | Developability |
| Example 1 | C | C |
| Example 2 | B | B |
| Example 3 | A | A |
| Example 4 | A | A |
| Example 5 | A | B |
| Example 6 | A | C |
| Example 7 | A | A |
| Example 8 | B | A |
| Example 9 | C | C |
| Example 10 | B | B |
| Example 11 | A | A |
| Example 12 | A | A |
| Example 13 | A | B |
| Example 14 | A | C |
| Example 15 | A | A |
| Example 16 | B | A |
| Example 17 | A | C |
| Example 18 | A | C |
| Example 19 | A | A |
| Example 20 | A | A |
| Example 21 | A | B |
| Example 22 | A | A |
| Example 23 | A | A |
| Example 24 | A | A |
| Example 25 | A | A |
| Example 26 | A | A |
| Example 27 | A | A |
| Example 28 | A | B |
| Example 29 | A | A |
| Example 30 | A | A |
| Example 31 | A | A |
| Example 32 | B | A |
| Example 33 | B | A |
| Example 34 | B | A |
| Example 35 | B | A |
| Example 36 | B | A |
| Example 37 | A | A |
| Example 38 | A | A |
| Example 39 | A | A |
| Example 40 | A | A |
| Example 41 | A | A |
| Example 42 | A | A |
| Example 43 | A | A |
| Example 44 | A | A |
| Example 45 | A | A |
| Example 46 | A | A |
| Example 47 | A | A |
| Comparative | D | D |
| example 1 | | |
| Comparative | D | D |
| example 2 | | |
| Comparative | D | D |
| example 3 | | |
| Comparative | D | D |
| example 4 | | |
| Comparative | D | D |
| example 5 | | |
| Comparative | D | D |
| example 6 | | |
| Comparative | D | C |
| example 7 | | |
| Comparative | D | B |
| example 8 | | |

As shown in the above table, the coloring compositions of Examples had good storage stability. Furthermore, the developability was also excellent. In addition, the films obtained by using the coloring compositions of Examples 1 to 7 and 9 to 47 had a green color, and the coloring compositions of Examples 1 to 7 and 9 to 47 could be preferably used as a coloring composition for forming a green pixel. In addition, the film obtained by using the coloring composition of Example 8 had a cyan color, and the coloring composition of Example 8 could be preferably used as a coloring composition for forming a cyan pixel.

With regard to the coloring compositions of Examples, even in a case where the types of the surfactant and the polymerization inhibitor are changed to other compounds described in the present specification, the same effects as those of each example can be obtained.

### Example 1001

A silicon wafer was coated with a coloring composition for forming a cyan pixel using a spin coating method so that the thickness of a film after film formation was 1.0 μm. Next, the coating film was heated using a hot plate at 100° C. for 2 minutes. Next, using an i-ray stepper exposure device FPA-3000 i5+ (manufactured by Canon Corporation), exposure was performed with light having an exposure amount of 1000 mJ/cm² through a mask having a dot pattern of 2 μm square. Next, puddle development was performed at 23° C. for 60 seconds using a tetramethylammonium hydroxide (TMAH) 0.3 mass % aqueous solution. Next, the coating film was rinsed by spin showering and was cleaned with pure water. Next, a cyan colored pattern (cyan pixel) was formed by heating at 200° C. for 5 minutes using a hot plate. In the same manner, a coloring composition for forming a magenta pixel and a coloring composition for forming a yellow pixel were sequentially patterned to form a magenta colored pattern (magenta pixel) and a yellow colored pattern (yellow pixel), respectively.

As the coloring composition for forming a cyan pixel, the coloring composition of Example 8 was used.

The coloring composition for forming a magenta pixel and the coloring composition for forming a yellow pixel will be described below.

The obtained color filter was incorporated into a solid-state imaging element according to a known method. The solid-state imaging element had a suitable image recognition ability.

(Coloring Composition for Forming Magenta Pixel)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid M1.

| | |
|---|---|
| C.I. Pigment Red 122 | 11.0 parts by mass |
| Resin C-1 | 6.7 parts by mass |
| PGMEA | 82.2 parts by mass |

Subsequently, after stirring a mixed solution obtained by mixing the following raw materials, the obtained mixed solution was filtered through a nylon filter (manufactured by Nihon Pall Corporation) having a pore size of 0.45 μm to obtain a coloring composition for forming a magenta pixel.

| | |
|---|---|
| Pigment dispersion liquid M1 | 62.4 parts by mass |
| Resin C-3 | 1.2 parts by mass |
| Polymerizable compound F-1 | 2.2 parts by mass |
| Photopolymerization initiator G-1 | 0.7 parts by mass |
| Surfactant I-1 | 4.2 parts by mass |
| Ultraviolet absorber 1 (compound having the following structure) | 0.4 parts by mass |
| Epoxy resin 1 (EHPE 3150 (manufactured by Daicel Corporation; 1,2- | 0.1 parts by mass |
| epoxy-4-(2-oxiranyl)cyclohexane adduct of 2,2′-bis(hydroxymethyl)- | |
| 1-butanol) | |
| PGMEA | 29.4 parts by mass |

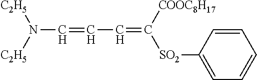

(Coloring Composition for Forming Yellow Pixel)

A mixed solution obtained by mixing the following raw materials was mixed and dispersed for 3 hours using a beads mill (zirconia beads having a diameter of 0.1 mm) to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was dispersed under a pressure of 2000 kg/cm³ at a flow rate of 500 g/min. This dispersion treatment was repeated up to 10 times, thereby obtaining a pigment dispersion liquid Y1.

### Raw Materials of Dispersion Liquid:

| | |
|---|---|
| C.I. Pigment Yellow 150 | 11.1 parts by mass |
| Resin C-1 | 6.7 parts by mass |
| PGMEA | 82.2 parts by mass |

Subsequently, after stirring a mixed solution obtained by mixing the following raw materials, the obtained mixed solution was filtered through a nylon filter (manufactured by Nihon Pall Corporation) having a pore size of 0.45 μm to obtain a coloring composition for forming a yellow pixel.

| | |
|---|---|
| Pigment dispersion liquid Y1 | 53.8 parts by mass |
| Resin C-3 | 3.3 parts by mass |
| Polymerizable compound F-1 | 2.4 parts by mass |
| Photopolymerization initiator G-1 | 0.9 parts by mass |
| Surfactant I-1 | 4.2 parts by mass |
| Ultraviolet absorber 1 | 0.7 parts by mass |
| PGMEA | 34.7 parts by mass |

What is claimed is:

1. A coloring composition comprising:
a colorant including a green pigment;
a compound A; and
a resin,
wherein an amount of the green pigment dissolved in 100 g of propylene glycol methyl ether acetate at 25° C. is less than 0.01 g,
an amount of the compound A dissolved in 100 g of propylene glycol methyl ether acetate at 25° C. is 0.01 g or more,
the coloring composition includes 0.1 to 10 parts by mass of the compound A with respect to 100 parts by mass of the green pigment, and
the green pigment and the compound A satisfy a relationship of the following expression (a),
−1.0 eV≤LUMO_{B}−LUMO_{A}≤1.0 eV (a)
where LUMO_{B} is an energy level of a lowest unoccupied molecular orbital of the green pigment, in units of eV, and
LUMO_{A} is an energy level of a lowest unoccupied molecular orbital of the compound A, in units of eV.

2. The coloring composition according to claim 1,
wherein the energy level of the lowest unoccupied molecular orbital of the compound A is −6.0 to −3.0 eV.

3. The coloring composition according to claim 1,
wherein a specific absorbance of the compound A at a maximum absorption wavelength of 450 to 800 nm, which is represented by the following expression (A_{λ1}), is 50 or less,
E¹=A¹/(c¹×l¹) (A_{λ1})
in the expression (A_{λ1}), E¹ represents the specific absorbance of the compound A at the maximum absorption wavelength of 450 to 800 nm, A¹ represents an absorbance of the compound A at the maximum absorption wavelength of 450 to 800 nm, l¹ represents a cell length in units of cm, and c¹ represents a concentration of the compound A in a solution, in units of mg/ml.

4. The coloring composition according to claim 1,
wherein the green pigment is a halogenated phthalocyanine compound.

5. The coloring composition according to claim 1,
wherein the compound A is a compound represented by any of Formula (1) to Formula (7), 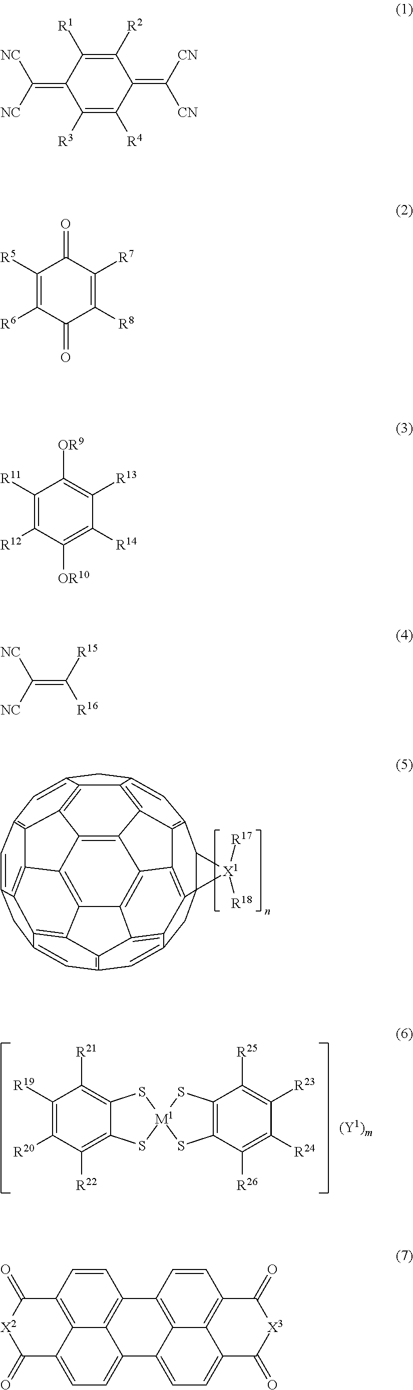
in Formula (1), R¹ to R⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹ and R², or R³ and R⁴ may be bonded to each other to form a ring,
in Formula (2), R⁵ to R⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxy carbonyl group, an aryloxy carbonyl group, a thiol group, an alkylthio group, an arylthio group, a nitro group, an amino group, a sulfo group, a cyano group, a silyl group, a boronyl group, or a phosphino group, and R⁵ and R⁶, or R⁷ and R⁸ may be bonded to each other to form a ring,
in Formula (3), R⁹ and R¹⁰ each independently represent a hydrogen atom, a hydrocarbon group, or a heterocyclic group, R¹¹ to R¹⁴ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹¹ and R¹², or R¹³ and R¹⁴ may be bonded to each other to form a ring,
in Formula (4), R¹⁵ and R¹⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁵ and R¹⁶ may be bonded to each other to form a ring,
in Formula (5), X¹ represents a carbon atom or a silicon atom, n represents an integer of 1 to 5, R¹⁷ and R¹⁸ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, and R¹⁷ and R¹⁸ may be bonded to each other to form a ring,
in Formula (6), M¹ represents a metal atom, R¹⁹ to R²⁶ each independently represent a hydrogen atom, a hydrocarbon group, a heterocyclic group, a halogen atom, a hydroxy group, an alkoxy group, an aryloxy group, an aldehyde group, an alkylcarbonyl group, an arylcarbonyl group, a carboxy group, an alkoxycarbonyl group, an aryloxycarbonyl group, a thiol group, an alkylthio group, an arylthio group, a nitro group, an amino group, a sulfo group, a cyano group, a silyl group, a boronyl group, or a phosphino group, R¹⁹ and R²¹, R¹⁹ and R²⁰, R²⁰ and R²², R²³ and R²⁵, R²³ and R²⁴, or R²⁴ and R²⁶ may be bonded to each other to form a ring, in a case where a moiety enclosed in [ ] in the formula is a cationic moiety, Y¹ represents a counter anion and m represents the number required to balance charges, in a case where a moiety enclosed in [ ] in the formula is an anionic moiety, Y¹ represents a counter cation and m represents the number required to balance charges, and in a case where a charge of a moiety enclosed in [ ] in the formula is neutralized in a molecule, m is 0, and
in Formula (7), X² and X³ each independently represent O or NRx, where Rx represents a hydrogen atom or a substituent.

6. The coloring composition according to claim 1,
wherein the resin includes a resin which includes a repeating unit having a graft chain.

7. The coloring composition according to claim 6,
wherein a weight-average molecular weight of the graft chain is 500 to 100000.

8. The coloring composition according to claim 1, further comprising:
a pigment derivative.

9. The coloring composition according to claim 1,
wherein the colorant further includes a yellow pigment.

10. The coloring composition according to claim 9,
wherein the yellow pigment is at least one selected from an isoindoline compound and a quinophthalone compound.

11. The coloring composition according to claim 1,
wherein a content of the colorant in a total solid content of the coloring composition is 45 mass % or more.

12. The coloring composition according to claim 1,
wherein a content of the green pigment in the colorant is 40 mass % or more.

13. The coloring composition according to claim 1, further comprising:
a polymerizable compound; and
a photopolymerization initiator.

14. The coloring composition according to claim 1,
wherein the coloring composition is a cyan coloring composition.

15. A film obtained by using the coloring composition according to claim 1.

16. A color filter comprising:
the film according to claim 15.

17. A solid-state imaging element comprising:
the film according to claim 15.

18. An image display device comprising:
the film according to claim 15.
